(19) United States
(12) Patent Application Publication
(10) Pub. No.: US 2010/0219522 A1
(43) Pub. Date: Sep. 2, 2010

(54) SEMICONDUCTOR DEVICE AND METHOD OF MANUFACTURING THE SAME, AND ELECTRONIC APPARATUS

(75) Inventor: Yuji Kunimoto, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/715,008

(22) Filed: Mar. 1, 2010

(30) Foreign Application Priority Data
Mar. 2, 2009 (JP) P.2009-048491

(51) Int. Cl. H01L 23/522; H01L 23/498; H01L 21/603

(52) U.S. Cl. 257/686; 257/700; 438/118; 438/121; 257/E21.519; 257/E23.145; 257/E23.062

(57) ABSTRACT

A first sealing resin seals a side surface of an electronic component and a side surface of a conductive member. A second sealing resin is provided on the first sealing resin, and seals an electrode pad and an electrode pad forming surface of the electronic component and a part of the conductive member. A multilayer wiring structure includes a plurality of stacked insulating layers and a wiring pattern and is provided on a surface of the second sealing resin from which a connecting surface of the electrode pad and a first connecting surface of the conductive member are exposed. The wiring pattern is connected to the connecting surface of the electrode pad and the first connecting surface of the conductive member.

This application claims priority to Japanese Patent Application No. 2009-048491, filed Mar. 2, 2009, in the Japanese Patent Office. The Japanese Patent Application No 2009-048491 is incorporated by reference in its entirety.

### TECHNICAL FIELD

The present disclosure relates to a semiconductor device and a method of manufacturing the semiconductor device, and an electronic apparatus, and more particularly to a semiconductor device including a multilayer wiring structure and an electronic component to be electrically connected to the multilayer wiring structure, and a method of manufacturing the semiconductor device and an electronic apparatus.

### RELATED ART

FIG. 1 is a sectional view showing a related-art electronic apparatus.

With reference to FIG. 1, a related-art electronic apparatus 200 includes semiconductor devices 201 and 202, and an internal connecting terminal 203. The semiconductor device 201 has a wiring board 211, an electronic component 212, an underfill resin 213 and an external connecting terminal 214.

The wiring board 211 is plate-shaped and has a multilayer wiring structure. The wiring board 211 has insulating layers 216 and 217 which are stacked, wiring patterns 219, 228 and 229, a pad 221, solder resist layers 222 and 226, and external connecting pads 223 and 224. The insulating layer 216 is provided on an upper surface 217A of the insulating layer 217.

The wiring pattern 219 and the pad 221 are provided on an upper surface 216A of the insulating layer 216. The wiring pattern 219 has pad portions 232 and 241 exposed from the solder resist layer 222. The pad 221 is exposed from the solder resist layer 222.

The solder resist layer 222 is provided on the upper surface 216A of the insulating layer 216. The external connecting pads 223 and 224 are provided on a lower surface 217B of the insulating layer 217. Lower surfaces of the external connecting pads 223 and 224 are exposed from the solder resist layer 226.

The solder resist layer 226 is provided on the lower surface 217B of the insulating layer 217. The wiring patterns 228 and 229 are provided in the insulating layers 216 and 217 which are stacked. The wiring pattern 228 is connected to the pad portion 241 and the external connecting pad 223. The wiring pattern 229 is connected to the pad 221 and the external connecting pad 224.

The electronic component 212 is disposed between the semiconductor device 201 and the semiconductor device 202. The electronic component 212 has an electrode pad 236. The electrode pad 236 is electrically connected to the pad portion 232 through a bump 237 (for example, a solder bump).

The underfill resin 213 is provided to fill a clearance between the electronic component 212 and the wiring board 211. The external connecting terminal 214 is provided on the lower surfaces of the external connecting pads 223 and 224.

The semiconductor device 202 is disposed above the semiconductor device 201. The semiconductor device 202 has the wiring board 241, an electronic component 243 and a mold resin 246. The wiring board 241 is plate-shaped and has pads 251, 252 and 254. The pad 251 is opposed to the pad portion 241 and is electrically connected to the pad portion 241 through the internal connecting terminal 203. The pad 252 is opposed to the pad 221 and is electrically connected to the pad 221 through the internal connecting terminal 203. The pad 254 is electrically connected to the pad 251 or the pad 252.

The electronic component 243 is bonded onto the wiring board 241 and is electrically connected to the pad 254 through a metal wire 255. The mold resin 246 is provided on the wiring board 241. The mold resin 246 seals the metal wire 255 and the electronic component 243.

The internal connecting terminal 203 has such a size (a height) that the electronic component 212 and the semiconductor device 202 do not come in contact with each other. The height of the internal connecting terminal 203 can be set to be 200 μm, for example (see Patent Document 1, for instance).

[Patent Document 1] JP-A-6-13541 Publication

In the related-art semiconductor device 201, however, the electronic component 212 disposed on an upper surface side of the wiring board 211 and the wiring board 211 (the multilayer wiring structure) are electrically connected to each other through the bump 237. For this reason, there is a problem in that a size in a height direction of the semiconductor device 201 is increased.

In the related-art semiconductor device 201, moreover, there is a problem in that a sufficient strength cannot be ensured in the case in which the wiring board 211 is a coreless substrate.

In the related-art electronic apparatus 200, furthermore, the height of the internal connecting terminal 203 for electrically connecting the semiconductor device 201 to the semiconductor device 202 is to be greater than a value obtained by adding a height of the electronic component 212 to that of the bump 237. For this reason, there is a problem in that a size in a thickness direction of the electronic apparatus 200 is increased.

Also in the case in which the electronic component 212 and the wiring board 211 are connected to each other through wire bonding, there is a problem in that the sizes in the thickness direction of the semiconductor device 201 and the electronic apparatus 200 are increased.

### SUMMARY

Exemplary embodiments of the present invention to provide a semiconductor device and a method of manufacturing the semiconductor device, and an electronic apparatus.

A semiconductor device according to an exemplary embodiment of the invention comprises:

an electronic component including an electrode pad, an electrode pad forming surface on which the electrode pad is formed, and a back face positioned on an opposite side to the electrode pad forming surface;

a conductive member which includes a first connecting surface disposed on an electrode pad forming surface side and a second connecting surface disposed on a back face side;

a first sealing resin which includes a first surface disposed on the electrode pad forming surface side and a second surface disposed on the back face side, and seals a side surface of the electronic component and a side surface of the conductive member;

a second sealing resin which is provided on the first surface of the first sealing resin, and seals the electrode pad, the electrode pad forming surface and a part of the conductive member in a state that a connecting surface of the electrode pad and the first connecting surface of the conductive member are exposed from the second sealing resin; and

a multilayer wiring structure which is provided on a surface of the second sealing resin from which the connecting surface of the electrode pad and the first connecting surface of the conductive member are exposed, and includes a plurality of stacked insulating layers and a wiring pattern,

wherein the wiring pattern is connected to the connecting surface of the electrode pad and the first connecting surface of the conductive member.

According to the exemplary embodiment of the invention, the multilayer wiring structure is provided to cover the connecting surface of the electrode pad of the electronic component, the first connecting surface of the conductive member and the surface of the second sealing resin, and the wiring pattern and the electrode pad are directly connected to each other. Consequently, it is possible to reduce a size in a thickness direction of the semiconductor device more greatly as compared with a related-art semiconductor device in which an electronic component and a multilayer wiring structure are electrically connected to each other through a bump or a metal wire.

Moreover, the second sealing resin is provided with the first sealing resin which seals the side surface of the conductive member and the side surface of the electronic component. Consequently, the first sealing resin functions as a reinforcing member for reinforcing a strength of the multilayer wiring structure. Therefore, it is possible to enhance a strength of the semiconductor device.

A method of manufacturing a semiconductor device including a multilayer wiring structure having a plurality of stacked insulating layers and a wiring pattern, and an electronic component having an electrode pad to be electrically connected to the wiring pattern, according to an exemplary embodiment of the invention, comprises:

a first step of forming a first sealing resin set in a semicuring state on a surface of a first support;

a second step of pushing a plurality of conductive members against the surface of the first support to penetrate through the first sealing resin, thereby providing the conductive members in the first sealing resin in a state in which a first connecting surface of each of the conductive members is protruded from the first sealing resin;

a third step of bonding the electronic component to a second support in such a manner that a flat surface of the second support comes in contact with a connecting surface of the electrode pad of the electronic component;

a fourth step of disposing the electronic component bonded to the second support and the first sealing resin opposite to each other and then pressing the first support and the second support to each other until the first connecting surface and the flat surface of the second support come in contact with each other, and thereafter curing the first sealing resin completely, thereby sealing a side surface of the electronic component;

a fifth step of removing the second support after the fourth step;

a sixth step of forming a second sealing resin on a surface of the first sealing resin positioned on an opposite side to a surface coming in contact with the first support in a state that the connecting surface of the electrode pad of the electronic component and the first connecting surface of the conductive member are exposed from the second sealing resin;

a seventh step of forming the multilayer wiring structure on the surface of the second sealing resin from which the connecting surface of the electrode pad of the electronic component and the first connecting surface of the conductive member are exposed in a state that the wiring pattern is connected to the connecting surface of the electrode pad of the electronic component and the first connecting surface of the conductive member; and

an eighth step of removing the first support after the seventh step.

According to the exemplary embodiment of the invention, the multilayer wiring structure is formed on the surface of the second sealing resin, the connecting surface of the electrode pad of the electronic component and the first connecting surface of the conductive member in such a manner that the wiring pattern and the connecting surface of the electrode pad of the electronic component are directly connected to each other. Consequently, it is possible to reduce the size in the thickness direction of the semiconductor device more greatly as compared with the related-art semiconductor device in which an electronic component and a multilayer wiring structure are electrically connected to each other through a bump or a metal wire.

Moreover, the electronic component bonded to the second support and the first sealing resin are disposed opposite to each other and the first support is then pressed in the direction turned toward the second support until the first connecting surface of the conductive member comes in contact with the flat surface of the second support, and the first sealing resin is thereafter cured completely. Consequently, the side surface of the electronic component is sealed so that the first sealing resin functions as a reinforcing member for reinforcing the strength of the multilayer wiring structure. Thus, it is possible to enhance the strength of the semiconductor device.

In the semiconductor device and the manufacturing method according to the exemplary embodiments of the invention, the conductive member may be a conductive ball or a metal post.

An electronic apparatus according to an exemplary embodiment of the invention comprises:

the above-mentioned semiconductor device; and

another semiconductor device which is disposed on a second surface side of the first sealing resin of the semiconductor device, and includes a connecting terminal being electrically connected to the second connecting surface of the conductive member of the semiconductor device.

The exemplary embodiments of the present invention enable a reduction in a size in a thickness direction of the semiconductor device and the electronic apparatus and an enhancement in a strength of the semiconductor device.

Other features and advantages may be apparent from the following detailed description, the accompanying drawings and the claims.

### BRIEF DESCRIPTION OF THE DRAWINGS

FIG. 1 is a sectional view showing a related-art electronic apparatus;

FIG. 2 is a sectional view showing an electronic apparatus according to a first embodiment of the invention;

FIG. 3 is a sectional view showing an electronic apparatus according to a variant of the first embodiment in accordance with the invention;

FIGS. 4 to 20 are views showing a process for manufacturing the electronic apparatus according to the first embodiment of the invention;

FIG. 21 is a sectional view showing an electronic apparatus according to a second embodiment of the invention; and

FIGS. 22 to 28 are views showing a process for manufacturing the electronic apparatus according to the second embodiment of the invention.

### DETAILED DESCRIPTION

Embodiments according to the invention will be described below with reference to the drawings.

### First Embodiment

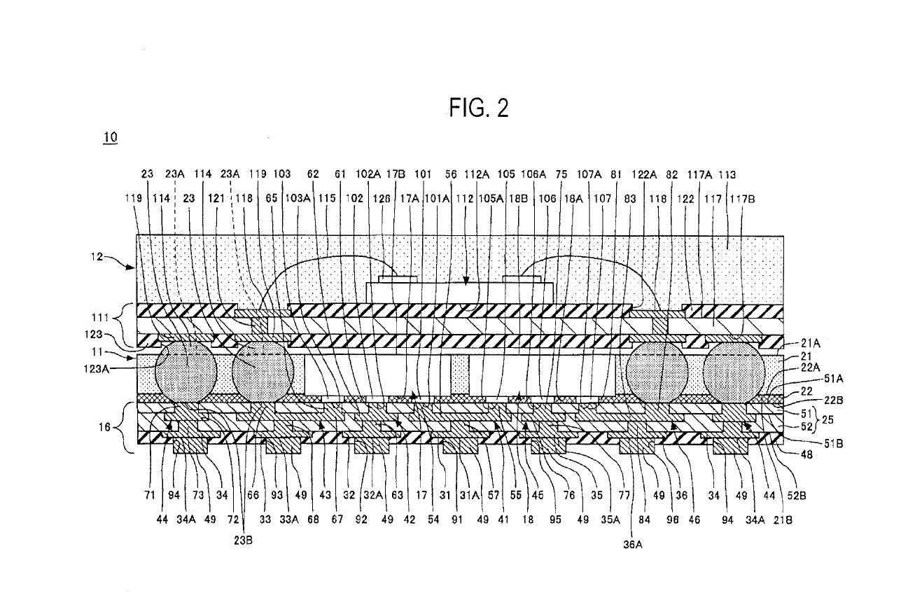

FIG. 2 is a sectional view showing an electronic apparatus according to a first embodiment of the invention.

With reference to FIG. 2, an electronic apparatus 10 according to the first embodiment has a semiconductor device 11 and a semiconductor device 12 to be another semiconductor device which is disposed above the semiconductor device 11 and is electrically connected to the semiconductor device 11.

The semiconductor device 11 has a multilayer wiring structure 16, electronic components 17 and 18, a first sealing resin 21, a second sealing resin 22, and a conductive ball 23 to be a conductive member.

The multilayer wiring structure 16 is provided on connecting surfaces 101A, 102A, 103A, 105A, 106A and 107A which, are disposed on the electronic components 17 and 18 and will be described below, a connecting surface 23B (a first connecting surface) which is provided on the conductive ball 23 and will be described below, and a multilayer, wiring structure forming surface 22B which is provided on the second sealing resin 22 and will be described below.

The multilayer wiring structure 16 has a stacked product 25, external connecting pads 31 to 36, wiring patterns 41 to 46, a solder resist layer 48, and an external connecting terminal 49.

The stacked product 25 has a structure in which a plurality of insulating layers 51 and 52 is stacked. The insulating layer 51 is provided between the insulating layer 52 and the second sealing resin 22. As the insulating layer 51, it is possible to use an insulating resin layer (such as an epoxy resin layer), for example.

The insulating layer 52 is provided on a lower surface 51B of the insulating layer 51. As the insulating layer 52, it is possible to use an insulating resin layer (such as an epoxy resin layer), for example.

The external connecting pads 31 to 36 are provided on a lower surface 52B of the insulating layer 52 (a second surface of the stacked product 25). The external connecting pad 31 has a connecting surface 31A on which the external connecting terminal 49 is to be provided. The external connecting pad 31 is connected to the wiring pattern 41. The external connecting pad 31 is electrically connected to the electronic components 17 and 18 through the wiring pattern 41.

The external connecting pad 32 has a connecting surface 32A on which the external connecting terminal 49 is to be provided. The external connecting pad 32 is connected to the wiring pattern 42. The external connecting pad 32 is electrically connected to the electronic component 17 through the wiring pattern 42.

The external connecting pad 33 has a connecting surface 33A on which the external connecting terminal 49 is to be provided. The external connecting pad 33 is connected to the wiring pattern 43. The external connecting pad 33 is electrically connected to the semiconductor device 12 and the electronic component 17 through the wiring pattern 43.

The external connecting pad 34 has a connecting surface 34A on which the external connecting terminal 49 is to be provided. The external connecting pad 34 is connected to the wiring pattern 44. The external connecting pad 34 is electrically connected to the semiconductor device 12 through the wiring pattern 44.

The external connecting pad 35 has a connecting surface 35A on which the external connecting terminal 49 is to be provided. The external connecting pad 35 is connected to the wiring pattern 45. The external connecting pad 35 is electrically connected to the electronic component 18 through the wiring pattern 45.

The external connecting pad 36 has a connecting surface 36A on which the external, connecting terminal 49 is to be provided. The external connecting pad 36 is connected to the wiring pattern 46. The external connecting pad 36 is electrically connected to the semiconductor device 12 and the electronic component 18 through the wiring pattern 46.

As materials of the external connecting pads 31 to 36 having the structures, for example, it is possible to use Cu.

The wiring patterns 41 to 46 are provided in the stacked product 25 to penetrate through the stacked product 25. The wiring pattern 41 has vias 54 and 55 to be first connecting portions, a wiring 56, and a via 57. The via 54 is provided to penetrate through the insulating layer 51 in an opposed part to an electrode pad 101 which is disposed on the electronic component 17 and will be described below. An upper end face of the via 54 is exposed from an upper surface 51A of the insulating layer 51 (a first surface of the stacked product 25). The upper end face of the via 54 is constituted on almost the level with the upper surface 51A of the insulating layer 51. The upper end of the via 54 is directly connected to the electrode pad 101. Consequently, the via 54 is electrically connected to the electronic component 17.

The via 55 is provided to penetrate through the insulating layer 51 in an opposed part to an electrode pad 105 which is disposed on the electronic component 18 and will be described below. An upper end face of the via 55 is exposed from the upper surface 51A of the insulating layer 51. The upper end face of the via 55 is constituted on almost the level with the upper surface 51A of the insulating layer 51. An upper end of the via 55 is directly connected to the electrode pad 105. Consequently, the via 55 is electrically connected to the electronic component 18.

The wiring 56 is provided on the lower surface 51B of the insulating layer 51 and lower end faces of the vias 54 and 55. The wiring 56 is connected to lower ends of the vias 54 and 55. The wiring 56 is electrically connected to the electronic components 17 and 18 through the vias 54 and 55.

The via 57 is provided to penetrate through the insulating layer 52 in a part positioned between the wiring 56 and the external connecting pad 31. An upper end of the via 57 is connected to the wiring 56. A lower end of the via 57 is connected to the external connecting pad 31. Consequently, the via 57 electrically connects the wiring 56 to the external connecting pad 31. As a material of the wiring pattern 41 having the structure, it is possible to use Cu, for example.

The wiring pattern 42 has a via 61 to be a first connecting portion, a via 63 and a wiring 62. The via 61 is provided to penetrate through the insulating layer 51 in an opposed part to an electrode pad 102 which is disposed on the electronic component 17 and will be described below. An upper end face of the via 61 is exposed from the upper surface 51A of the insulating layer 51. The upper end face of the via 61 is constituted on almost the level with the upper surface 51A of the insulating layer 51. An upper end of the via 61 is directly connected to the electrode pad 102. Consequently, the via 61 is electrically connected to the electronic component 17.

The wiring 62 is provided on the lower surface 51B of the insulating layer 51 and a lower end face of the via 61. The wiring 62 is connected to a lower end of the via 61. Consequently, the wiring 62 is electrically connected to the electronic component 17 through the via 61.

The via 63 is provided to penetrate through the insulating layer 52 in a part positioned between the wiring 62 and the external connecting pad 32. An upper end of the via 63 is connected to the wiring 62. A lower end of the via 63 is connected to the external connecting pad 32. Consequently, the via 63 electrically connects the wiring 62 to the external connecting pad 32. As a material of the wiring pattern 42 having the structure, it is possible to use Cu, for example.

The wiring pattern 43 has a via 65 to be a first connecting portion, a via 66 to be a second connecting portion, a wiring 67, and a via 68. The via 65 is provided to penetrate through the insulating layer 51 in an opposed part to an electrode pad 103 which is disposed on the electronic component 17 and will be described below. An upper end face of the via 65 is exposed from the upper surface 51A of the insulating layer 51. The upper end face of the via 65 is constituted on almost the level with the upper surface 51A of the insulating layer 51. An upper end of the via 65 is directly connected to the electrode pad 103. Consequently, the via 65 is electrically connected to the electronic component 17.

The via 66 is provided to penetrate through the insulating layer 51 in an opposed part to the conductive ball 23. An upper end face of the via 66 is exposed from the upper surface 51A of the insulating layer 51. The upper end face of the via 66 is constituted on almost the level with the upper surface 51A of the insulating layer 51. An upper end of the via 66 is directly connected to the conductive ball 23. Consequently, the via 66 is electrically connected to the semiconductor device 12 through the conductive ball 23.

The wiring 67 is provided on the lower surface 51B of the insulating layer 51 and lower end faces of the vias 65 and 66. The wiring 67 is connected to lower ends of the vias 65 and 66. The wiring 67 is electrically connected to the electronic component 17 and the semiconductor device 12 through the vias 65 and 66.

The via 68 is provided to penetrate through the insulating layer 52 in a part positioned between the wiring 67 and the external connecting pad 33. An upper end of the via 68 is connected to the wiring 67. A lower end of the via 68 is connected to the external connecting pad 33. Consequently, the via 68 electrically connects the wiring 67 to the external connecting pad 33. As a material of the wiring pattern 43 having the structure, it is possible to use Cu, for example.

The wiring pattern 44 has a via 71 to be a second connecting portion, a wiring 72 and a via 73. The via 71 is provided to penetrate through the insulating layer 51 in an opposed part to the conductive ball 23. An upper end face of the via 71 is exposed from the upper surface 51A of the insulating layer 51. The upper end face of the via 71 is constituted on almost the level with the upper surface 51A of the insulating layer 51. An upper end of the via 71 is directly connected to the conductive ball 23. Consequently, the via 71 is electrically connected to the semiconductor device 12 through the conductive ball 23.

The wiring 72 is provided on the lower surface 51B of the insulating layer 51 and a lower end face of the via 71. The wiring 72 is connected to a lower end of the via 71. The wiring 72 is electrically connected to the semiconductor device 12 through the via 71.

The via 73 is provided to penetrate through the insulating layer 52 in a part positioned between the wiring 72 and the external connecting pad 34. An upper end of the via 73 is connected to the wiring 72. A lower end of the via 73 is connected to the external connecting pad 34. Consequently, the via 73 electrically connects the wiring 72 to the external connecting pad 34. As a material of the wiring pattern 44 having the structure, it is possible to use Cu, for example.

The wiring pattern 45 has a via 75 to be a first connecting portion, a wiring 76 and a via 77. The via 75 is provided to penetrate through the insulating layer 51 in an opposed part to an electrode pad 106 which is disposed on the electronic component 18 and will be described below. An upper end face of the via 75 is exposed from the upper surface 51A of the insulating layer 51. The upper end face of the via 75 is constituted on almost the level with the upper surface 51A of the insulating layer 51. An upper end of the via 75 is directly connected to the electrode pad 106. Consequently, the via 75 is electrically connected to the electronic component 18.

The wiring 76 is provided on the lower surface 51B of the insulating layer 51 and a lower end face of the via 75. The wiring 76 is connected to a lower end of the via 75. The wiring 76 is electrically connected to the electronic component 18 through the via 75.

The via 77 is provided to penetrate through the insulating layer 52 in a part positioned between the wiring 76 and the external connecting pad 35. An upper end of the via 77 is connected to the wiring 76. A lower end of the via 77 is connected to the external connecting pad 35. Consequently, the via 77 electrically connects the wiring 76 to the external connecting pad 35. As a material of the wiring pattern 45 having the structure, it is possible to use Cu, for example.

The wiring pattern 46 has a via 81 to be a first connecting portion, a via 82 to be a second connecting portion, a wiring 83, and a via 84. The via 81 is provided to penetrate through the insulating layer 51 in an opposed part to an electrode pad 107 which is disposed on the electronic component 18 and will be described below. An upper end face of the via 81 is exposed from the upper surface 51A of the insulating layer 51. The upper end face of the via 81 is constituted on almost the level with the upper surface 51A of the insulating layer 51. An upper end of the via 81 is directly connected to the electrode pad 107. Consequently, the via 81 is electrically connected to the electronic component 18.

The via 82 is provided to penetrate through the insulating layer 51 in an opposed part to the conductive ball 23. An upper end face of the via 82 is exposed from the upper surface 51A of the insulating layer 51. The upper end face of the via 82 is constituted on almost the level with the upper surface 51A of the insulating layer 51. An upper end of the via 82 is directly connected to the conductive ball 23. Consequently, the via 82 is electrically connected to the semiconductor device 12 through the conductive ball 23.

The wiring 83 is provided on the lower surface 51B of the insulating layer 51 and lower end faces of the vias 81 and 82. The wiring 83 is connected to lower ends of the vias 81 and 82. The wiring 83 is electrically connected to the semiconductor device 12 and the electronic component 18 through the vias 81 and 82.

The via 84 is provided to penetrate through the insulating layer 52 in a part positioned between the wiring 83 and the external connecting pad 36. An upper end of the via 84 is connected to the wiring 83. A lower end of the via 84 is connected to the external connecting, pad 36. Consequently, the via 84 electrically connects the wiring 83 to the external connecting pad 36. As a material of the wiring pattern 46 having the structure, it is possible to use Cu, for example.

The solder resist layer 48 is provided on the lower surface 52B of the insulating layer 52. The solder resist layer 48 has opening portions 91 to 96. The opening portion 91 is formed to expose the connecting surface 31A. The opening portion 92 is formed to expose the connecting surface 32A. The opening portion 93 is formed to expose the connecting surface 33A. The opening portion 94 is formed to expose the connecting surface 34A. The opening portion 95 is formed to expose the connecting surface 35A. The opening portion 96 is formed to expose the connecting surface 36A.

The external connecting terminal 49 is provided on the connecting surfaces 31A, 32A, 33A, 34A, 35A and 36A, respectively. The external connecting terminal 49 is a terminal to be connected to a pad provided on a mounting substrate such as a mother board (not shown) when the electronic apparatus 10 is to, be connected to the mounting substrate. As the external connecting terminal 49, it is possible to use a metal post (such as a Cu post), for example. Although FIG. 2 shows, as an example, the case in which the metal post is used as the external connecting terminal 49, it is also possible to use a conductive ball as the external connecting terminal 49 in place of the metal post, for instance.

A thickness of the multilayer wiring structure 16 constituted above is set to be smaller than that of the first sealing resin 21. For example, in the case in which the thickness of the first sealing resin 21 is 100 to 300 μm, the thickness of the multilayer wiring structure 16 can be set to be 2.0 to 100 μm.

The electronic component 17 is a thinned plate. The electronic component 17 includes the electrode pads 101 to 103 having the connecting surfaces 101A, 102A and 103A, an electrode pad forming surface 17A, and a back face 17B disposed on an opposite side to the electrode pad forming surface 17A.

A side surface of the electronic component 17 is sealed with the first sealing resin 21. Moreover, the electrode pads 101 to 103 and the electrode pad forming surface 17A are sealed with the second sealing resin 22.

The connecting surfaces 101A, 102A and 103A are provided in contact with the upper surface 51A of the insulating layer 51. The electrode pads 101 to 103 are provided on the electrode pad forming surface 17A. The electrode pads 101 to 103 are protruded from the electrode pad forming surface 17A.

The upper end of the via 54 is directly connected to the connecting surface 101A of the electrode pad 101. Consequently, the electrode pad 101 is electrically connected to the electronic component 18 and the external connecting pad 31 through the wiring pattern 41.

The upper end of the via 61 is directly connected to the connecting surface 102A of the electrode pad 102. Consequently, the electrode pad 102 is electrically connected to the external connecting pad 32 through the wiring pattern 42.

The upper end of the via 65 is directly connected to the connecting surface 103A of the electrode pad 103. Consequently, the electrode pad 103 is electrically connected to the semiconductor device 12 and the external connecting pad 33 through the wiring pattern 43.

The back face 17B of the electronic component 17 is exposed from the first sealing resin 21. A thickness of the electronic component 17 can be set to be 100 to 200 μm, for example.

The electronic component 18 is a thinned plate. The electronic component 18 includes the electrode pads 105 to 107 having the connecting surfaces 105A, 106A and 107A, an electrode pad forming surface 18A, and a back face 18B disposed on an opposite side to the electrode pad forming surface 18A.

A side surface of the electronic component 18 is sealed with the first sealing resin 21. Moreover, the electrode pads 105 to 107 and the electrode pad forming surface 18A are sealed with the second sealing resin 22.

The connecting surfaces 105A, 106A and 107A are provided in contact with the upper surface 51A of the insulating layer 51. The electrode pads 105 to 107 are provided on the electrode pad forming surface 18A. The pads 105 to 107 are protruded from the electrode pad forming surface 18A.

The upper end of the via 55 is directly connected to the connecting surface 105A of the electrode pad 105. Consequently, the electrode pad 105 is electrically connected to the electronic component 17 and the external connecting pad 31 through the wiring pattern 41.

The upper end of the via 75 is directly connected to the connecting surface 106A of the electrode pad 106. Consequently, the electrode pad 106 is electrically connected to the external connecting pad 35 through the wiring pattern 45.

The upper end of the via 81 is directly connected to the connecting surface 107A of the electrode pad 107. Consequently, the electrode pad 107 is electrically connected to the semiconductor device 12 and the external connecting pad 36 through the wiring pattern 46.

The back face 18B of the electronic component 18 is exposed from the first sealing resin 21. The back faces 17B and 18B of the electronic components 17 and 18 are disposed on the same plane. A thickness of the electronic component 18 can be set to be 100 to 200 μm, for example.

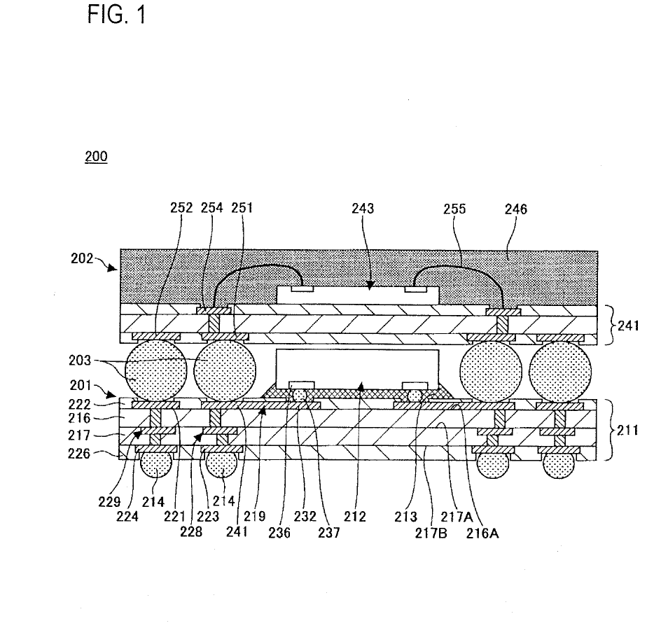

By directly connecting the electrode pads 101 to 103 to the vias 54, 61 and 65 constituting the wiring patterns 41 to 43 and directly connecting the electrode pads 105 to 107 to the vias 55, 75 and 81 constituting the wiring patterns 41, 45 and 46, thus, it is possible to reduce a size in a thickness direction of the semiconductor device 11 more greatly as compared with the related-art semiconductor device 200 in which the electronic component 212 and the wiring pattern 219 are electrically connected to each other through the bump or the metal wire (see FIG. 1).

As the electronic components 17 and 18 having the structure, it is possible to use a semiconductor chip for a CPU in both of them, the semiconductor chip for a CPU in one of them and a semiconductor chip for a memory in the other or the semiconductor chip for a CPU in one of them and a GPU (Graphics Processing Unit) in the other, for example.

The first sealing resin 21 is completely cured and is provided on an upper surface 22A of the second sealing resin 22. The first sealing resin 21 seals the side surfaces of the electronic components 17 and 18, and furthermore, seals a side surface of the conductive ball 23. An upper surface 21A (a flat surface) of the first sealing resin 21 and the back faces 17B and 18B of the electronic components 17 and 18 are disposed on the same plane.

The first sealing resin 21 is thicker than the multilayer wiring structure 16 and the second sealing resin 22. In the case in which the thickness of the second sealing resin 22 is 10 μm, the thickness of the first sealing resin 21 (the thickness of the first sealing resin 21 in complete curing) can be set to be 200 μm, for example. In this case, the thickness of the multilayer wiring structure 16 can be set to be 100 μm, for example.

As the first sealing resin 21, for instance, it is possible to use a resin layer having an adhesiveness (more specifically, a die attach film, for example).

Thus, the first sealing resin 21 for sealing the side surfaces of the electronic components 17 and 18 and sealing the side surface of the conductive ball 23 is provided on the upper surface 22A of the second sealing resin 22. Consequently, the first sealing resin 21, having a greater thickness than that of the second sealing resin 22 functions as a reinforcing member for reinforcing a strength of the multilayer wiring structure 16. Therefore, it is possible to reinforce the strength, of the multilayer wiring structure 16. In particular, it is effective for the case in which the multilayer wiring structure 16 is a coreless substrate.

The second sealing resin 22 is provided to fill in a clearance between a lower end of the conductive ball 23 and the multilayer wiring structure 16, a clearance between the electronic components 17 and 18 and the multilayer wiring structure 16, and a clearance between the first sealing resin 21 and the multilayer wiring structure 16. The second sealing resin 22 seals the electrode pad forming surfaces 17A and 18A of the electronic components 17 and 18, the electrode pads 101 to 103 and 105 to 107, and a lower end of the conductive ball 23.

The second sealing resin 22 has the multilayer wiring structure forming surface 22B disposed on a plane passing through the connecting surfaces 23B, 101A, 102A, 103A, 105A, 106A and 107A. The multilayer wiring structure forming surface 22B serves as a surface on which the multilayer wiring structure 16 is to be formed.

As the second sealing resin 22, for example, it is possible to use a mold resin. As described above, the second sealing resin 22 has a smaller thickness than that of the first sealing resin 21.

The conductive ball 23 is disposed to surround the electronic components 17 and 18. The side surface of the conductive ball 23 is sealed with the first sealing resin 21. The conductive ball 23 has the connecting surface 23B to be the first connecting surface and a connecting surface 23A to be a second connecting surface. The connecting surface 23B is set to be flat. The connecting surface 23B is directly connected to the upper end of one of the vias 66, 71 and 82.

The connecting surface 23A is flat. The conductive ball 23 in a corresponding part to the connecting surface 23A is bonded to an internal connecting terminal 114 which is provided in the semiconductor device 12 and will be described below. The connecting surface 23A is formed on the conductive ball 23 before bonding to the internal connecting terminal 114. The connecting surface 23A is disposed on a plane passing through the back faces 1713 and 18B of the electronic components 17 and 18 and the upper surface 21A of the first sealing resin 21. In other words, the connecting surface 23A of the conductive ball 23, the back faces 17B and 18B of the electronic components 17 and 18, and the upper surface 21A of the first sealing resin 21 are disposed on the same plane. Consequently, an upper surface of the semiconductor device 11 (a surface of the semiconductor device 11 on a side where the semiconductor device 12 is to be connected) is set to be flat.

By disposing the connecting surface 23A of the conductive ball 23, the back faces 17B and 18B of the electronic components 17 and 18, and the upper surface 21A of the first sealing resin 21 on the same plane to cause the upper surface of the semiconductor device 11 to be flat, thus, it is possible to reduce a diameter of the internal connecting terminal 114 which is provided in the semiconductor device 12 and is bonded to the conductive ball 23. Therefore, it is possible to reduce the size in the thickness direction of the electronic apparatus 10.

According to the semiconductor device in accordance with the embodiment, the electrode pads 101 to 103 provided in the electronic component 17 and the vias 54, 61 and 65 constituting the wiring patterns 41 to 43 are directly connected to each other, and furthermore, the electrode pads 105 to 107 provided in the electronic component 18 and the vias 55, 75 and 81 constituting the wiring patterns 41, 45 and 46 are directly connected to each other. Consequently, it is possible to reduce the size in the thickness direction of the semiconductor device 11 more greatly as compared with the related-art semiconductor device 200 in which the electronic component 212 and the wiring pattern 219 are electrically connected to each other through the bump or the metal wire (see FIG. 1).

Moreover, the first sealing resin 21 for sealing the side surfaces of the electronic components 17 and 18 and sealing the side surface of the conductive ball 23 is provided on the upper surface 22A of the second sealing resin 22. Consequently, the first sealing resin 21 having a greater thickness than that of the second sealing resin 22 functions as a reinforcing member for reinforcing a strength of the multilayer wiring structure 16. Therefore, it is possible to reinforce the strength of the multilayer wiring structure 16. In particular, it is effective for the case in which the multilayer wiring structure 16 is a coreless substrate.

The semiconductor device 12 includes a wiring board 111, an electronic component 112, a mold resin 113 and the internal connecting terminal 114. The wiring board 111 has a substrate body 117, pads 118 and 119, a wiring pattern 121, and solder resist layers 122 and 123.

The substrate body 117 is plate-shaped. As the substrate body 117, for example, it is possible to use a stacked product in which a plurality of insulating resin layers (such as epoxy resin layers) is stacked.

The pad 118 is provided on an upper surface 117A of the substrate body 117. The pad 118 is connected to one of ends of a metal wire 115 (for example, an Au wire) and an upper end of the wiring pattern 121. The pad 118 is electrically connected to the electronic component 112 through the metal wire 115. As a material of the pad 118, for example, it is possible to use Cu.

The pad 119 is provided on a lower surface 117B of the substrate body 117. The pad 119 is connected to a lower end of the wiring pattern 121 and the internal connecting terminal 114. The pad 119 is electrically connected to the pad 118 through the wiring pattern 121, and furthermore, is electrically connected to the semiconductor device 11 through the internal connecting terminal 114. As a material of the pad 119, for example, it is possible to use Cu.

The wiring pattern 121 is provided in the substrate body 117 to penetrate through the substrate body 117. The wiring pattern 121 can be constituted by a plurality of wirings and vias (not shown), for example. An upper end of the wiring pattern 121 is connected to the pad 118 and the lower end of the wiring pattern 121 is connected to the pad 119. As a material of the wiring pattern 121, for, example, it is possible to use Cu.

The solder resist layer 122 is provided on the upper surface 117A of the substrate body 117. The solder resist layer 122 has an opening portion 122A for exposing an upper surface of the pad 118.

The solder resist layer 123 is provided on the lower surface 117B of the substrate body 117. The solder resist layer 123 has an opening portion 123A for exposing a lower surface of the pad 119.

The electronic component 112 has a plurality of electrode pads 126. The electronic component 112 is bonded onto the solder resist layer 122 in such a manner that a surface 112A of the electronic component 112 on a side where the electrode pad 126 is not formed comes in contact with an upper surface of the solder resist layer 122. The electrode pad 126 is connected to the other end of the metal wire 115. Consequently, the electronic component 112 is electrically connected to the wiring board 111 through the metal wire 115. As the electronic component 112, for example, it is possible to use an active element (a semiconductor chip for a memory).

The mold resin 113 is provided on the upper surface of the pad 118 and the upper surface of the solder resist 122 in order to cover the electronic component 112 and the metal wire 115. The mold resin 113 serves to seal the electronic component 112 and the metal wire 115. As a material of the mold resin 113, for example, it is possible to use an epoxy resin.

The internal connecting terminal 114 is provided on the pad 119 in a part exposed from the opening portion 123A. The internal connecting terminal 114 is bonded to the conductive ball 23 provided in the semiconductor device 11. Consequently, the semiconductor device 11 and the semiconductor device 12 are electrically connected to each other. The internal connecting terminal 114 which has not been bonded to the conductive ball 23 can be caused to take an almost spherical shape, for example. A diameter (a height) of the internal connecting terminal 114 can be set to be 30 μm, for example.

According to the electronic apparatus in accordance with the embodiment, the connecting surface 23A of the conductive ball 23, the back faces 17B and 18B of the electronic components 17 and 18, and the upper surface 21A of the first sealing resin 21 are disposed on the same plane and the upper surface of the semiconductor device 11 (the surface of the semiconductor device 11 on the side where the semiconductor device 12 is to be connected) is caused to be flat. Consequently, it is possible to reduce the diameter of the internal connecting terminal 114 which is provided in the semiconductor device 12 and is bonded to the conductive ball 23 (more specifically, the height of the internal connecting terminal 114). Therefore, it is possible to reduce the size in the thickness direction of the electronic apparatus 10.

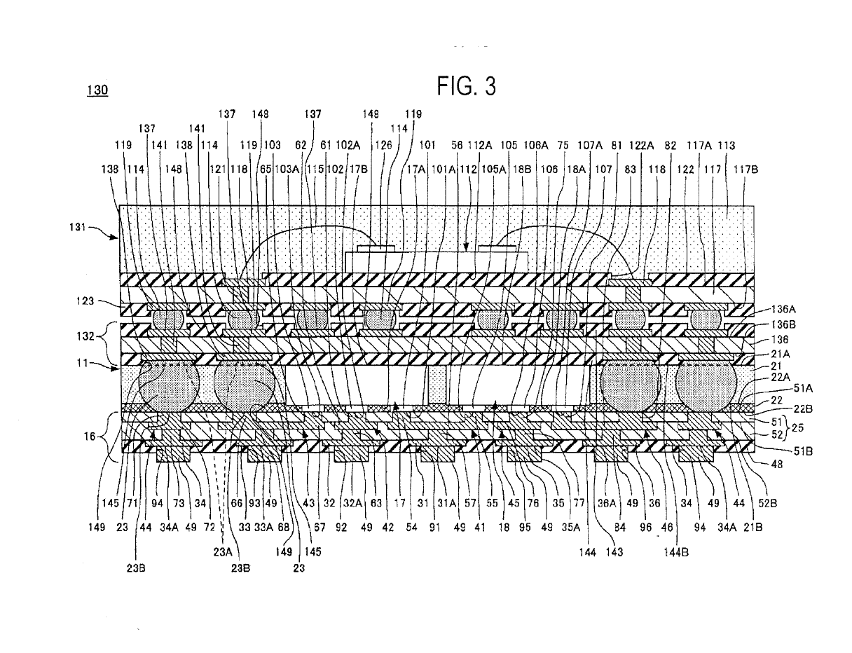

FIG. 3 is a sectional view showing an electronic apparatus according to a variant of the first embodiment in accordance with the invention. In FIG. 3, the same components as those of the electronic apparatus 10 according to the first embodiment have the same designations.

With reference to FIG. 3, an electronic apparatus 130 according to a variant of the first embodiment has the same structure as that of the electronic apparatus 10 except that a semiconductor device 131 is provided in place of the semiconductor device 12 disposed in the electronic apparatus 10 according to the first embodiment and a wiring board 132 is further provided.

The semiconductor device 131 has the same structure as that of the semiconductor device 12 except that the pad 119 provided in the semiconductor device 12 is also provided on a lower surface 117B of a substrate body 117 in an opposed part to electronic components 17 and 18. In other words, the semiconductor device 131 has a structure in which the pad 119 is disposed over the whole lower surface 117B of the substrate body 117.

The wiring board 132 is disposed between a semiconductor device 11 and the semiconductor device 131. The wiring board 132 has a substrate body 136, pads 137 and 138, a wiring pattern 141, solder resist layers 143 and 144, and a solder 145.

The substrate body 136 is plate-shaped. As the substrate body 136, for example, it is possible to use a stacked product in which a plurality of insulating resin layers (such as epoxy resin layers) is stacked.

The pad 137 is provided on an upper surface 136A of the substrate body 136. A plurality of pads 137 is provided on the upper surface 136A of the substrate body 136. The pad 137 is disposed opposite to the pad 119 provided in the semiconductor device 131. An upper surface of the pad 137 is connected to an internal connecting terminal 114. Consequently, the pad 137 is electrically connected to the semiconductor device 131 through the internal connecting terminal 114. As a material of the pad 137, for example, it is possible to use Cu.

A plurality of pads 138 is provided on a lower surface 136B of the substrate body 136. The pads 138 are disposed opposite to an upper end of one of vias 66, 71 and 82. A solder 145 bonded to a conductive ball 23 is provided on a lower surface of the pad 138. The pad 138 is electrically connected to the conductive ball 23 through the solder 145. Consequently, the pad 138 is electrically connected to the semiconductor device 11 through the solder 145. As a material of the pad 138, for example, it is possible to use Cu.

The wiring pattern 141 is provided in the substrate body 136 to penetrate through the substrate body 136. The wiring pattern 141 can be constituted by a plurality of wirings and vias (not shown), for example. An upper end of the wiring pattern 141 is connected to the pad 137 and a lower end of the wiring pattern 141 is connected to the pad 138. Consequently, the wiring pattern 141 electrically connects the pads 137 and 138 to each other.

A solder resist layer 143 is provided on the upper surface 136A of the substrate body 136. The solder resist layer 143 has an opening portion 148 for exposing an upper surface of the pad 137. The solder resist layer 143 is opposed to a solder resist layer 123 provided in the semiconductor device 131 in a state in which a clearance is provided between the solder resist layer 143 and the solder resist layer 123.

The solder resist layer 144 is provided on the lower surface 136B of the substrate body 136. The solder resist layer 144 has an opening portion 149 for exposing a lower surface of the pad 138. A lower surface 14413 of the solder resist layer 144 is provided in contact with back faces 17B and 18B of the electronic components 17 and 18 and an upper surface 21A of a first sealing resin 21 which are disposed on the same plane.

The solder 145 is provided on the lower surface of the pad 138 in a part exposed from the opening portion 149. The solder 145 is bonded to the conductive ball 23.

According to the electronic apparatus in accordance with the variant of the embodiment, the wiring board 132 for electrically connecting the semiconductor devices 11 and 131 to each other is provided between the semiconductor devices 11 and 131. Consequently, it is possible to increase the number of the internal connecting terminals 114 for electrically connecting the semiconductor devices 11 and 131 to each other.

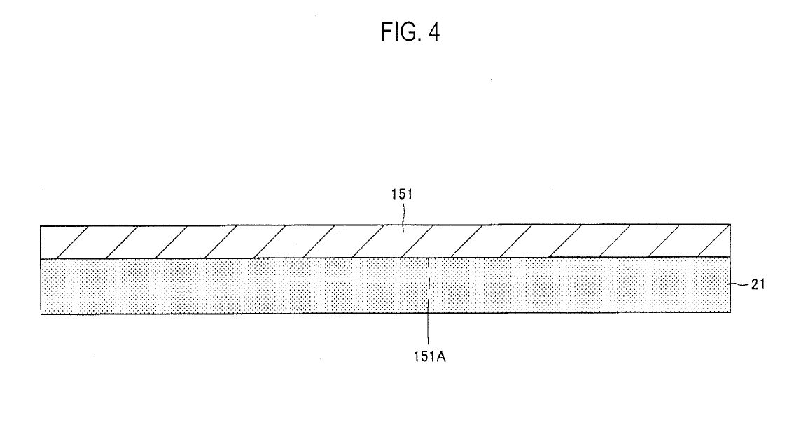

FIGS. 4 to 20 are views showing a process for manufacturing the electronic apparatus according to the first embodiment of the invention. In FIGS. 4 to 20, the same components as those of the electronic apparatus 10 according to the first embodiment have the same designations.

With reference to FIGS. 4 to 20, description will be given to a method of manufacturing the electronic apparatus 10 according to the first embodiment. In the description of the method of manufacturing the electronic apparatus 10 according to the first embodiment, explanation will also be given to a method of manufacturing the semiconductor device 11 according to the first embodiment.

First of all, at a step shown in FIG. 4, a first sealing resin 21 set in a semicuring state is formed on a surface 151A of a first support 151 (a first sealing resin forming step).

As the first support 151, for example, it is possible to use a silicon substrate, a metal plate (such as a Cu plate) or a glass plate. A thickness of the first support 151 can be set to be 300 μm, for example.

As the first sealing resin 21, for example, it is possible to use a die attach film set in the semicuring state. The first sealing resin 21 is formed by sticking the die attach film set in the semicuring state onto the surface 151A of the support 151, for example. A thickness of the first sealing resin 21 in this stage is greater than that of the first sealing resin 21 shown in FIG. 2 described above (for example, 200 μm). The thickness of the first sealing resin 21 shown in FIG. 4 can be set to be 800 μm, for example.

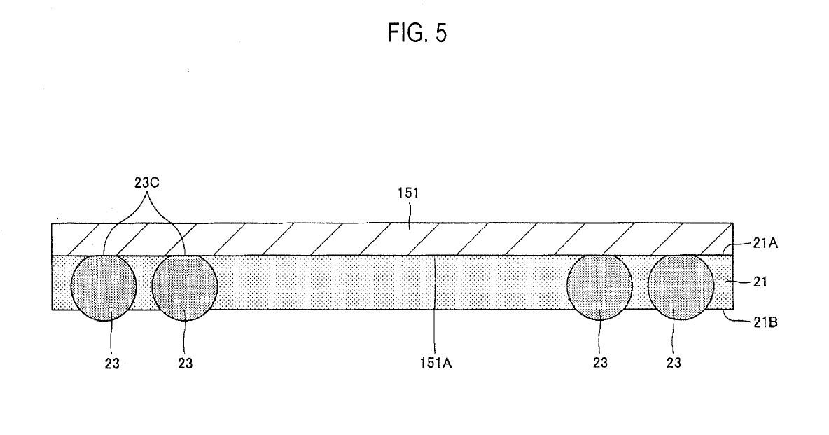

At a step shown in FIG. 5, next, a plurality of conductive balls 23 having a larger diameter than a value of the thickness of the first sealing resin 21 set in the semicuring state is prepared and one of ends of each of the conductive balls 23 is then pushed against the surface 151A of the first support 151 to penetrate through the first sealing resin 21 from a lower surface 21B side of the first sealing resin 21 so that a flat surface 23C is formed on the end of the conductive ball 23. In this case, the conductive balls 23 are provided in the first sealing resin 21 in such a manner that the other ends of the conductive balls 23 are exposed from the lower surface 21B of the first sealing resin 21 (a conductive ball providing step).

As the conductive ball 23, for example, it is possible to use a solder ball. In the case in which the thickness of the first sealing resin 21 set in the semicuring state is 800 μm, the diameter of the conductive ball 23 can be set to be 1000 μm, for example.

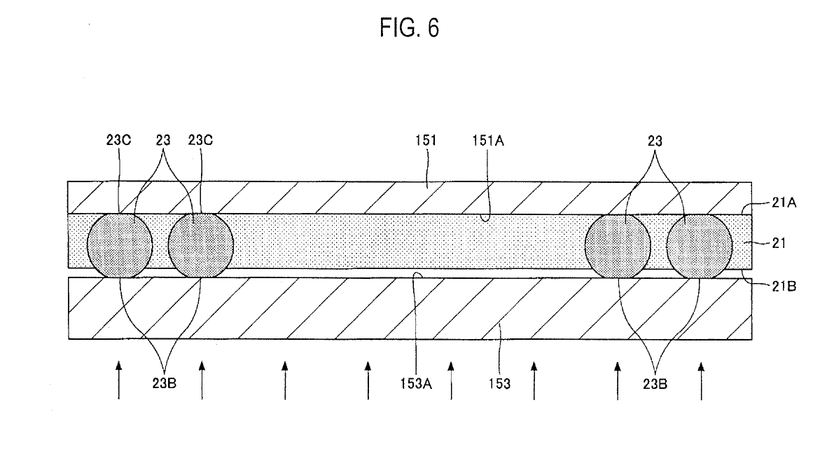

At a step shown in FIG. 6, subsequently, the other ends of the conductive balls 23 are crushed (coining) by means of a pressing member 153 having a flat pressing surface 153A which is opposed to the other ends of the conductive balls 23 from a lower surface side of the structure illustrated in FIG. 5. Consequently, a connecting surface 23B to be a first connecting surface which is protruded from the lower surface 21B of the first sealing resin 21 is formed on the other end of each of the conductive balls 23 (a conductive ball crushing step). The connecting surface 23B is set to be flat.

Thus, the connecting surface 23B to be connected to one of vias 66, 71 and 82 is formed, and furthermore, heights of the conductive balls 23 can be set to be equal to each other.

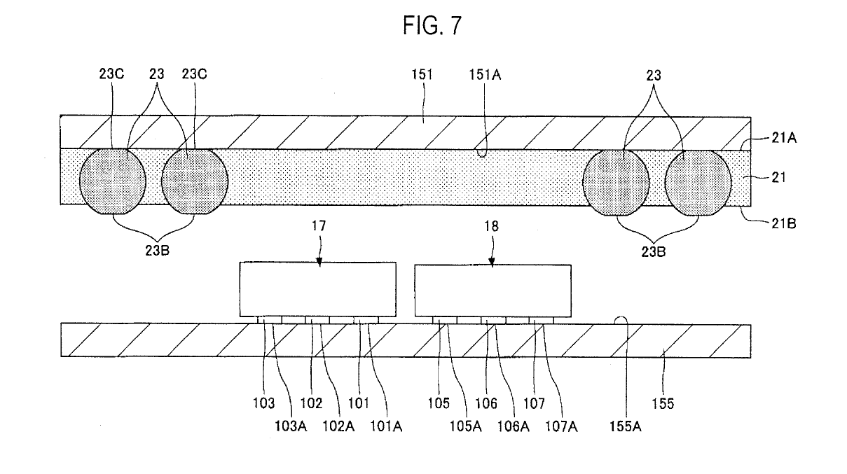

At a step shown in FIG. 7, then, electronic components 17 and 18 are bonded to a flat surface 155A of a second support 155 in such a manner that the flat surface 155A of the second support 155 comes in contact with connecting surfaces 101A, 102A, 103A, 105A, 106A and 107A of electrode pads 101 to 103 and 105 to 107 (an electronic component bonding step).

More specifically, the electronic components 17 and 18 are bonded to the flat surface 155A of the second support 155 by using a die attach film (not shown), for example. As the second support 155, it is possible to use a silicon substrate, a metal plate (such as a Cu plate) or a glass plate, for example. A thickness of the second support 155 can be set to be 300 μm, for example.

The electronic component 17 is not a thinned plate. The electronic component 17 includes the electrode pads 101 to 103 having the connecting surfaces 101A, 102A and 103A. A thickness of the electronic component 17 can be set to be 750 μm, for example.

The electronic component 18 is not a thinned plate. The electronic component 18 includes the electrode pads 105 to 107 having the connecting surfaces 105A, 106A and 107A. A thickness of the electronic component 18 can be set to be 750 μm, for example.

As the electronic components 17 and 18 having the structures, for example, it is possible to use a semiconductor chip for a CPU in both of them, the semiconductor chip for a CPU in one of them and a semiconductor chip for a memory in the other, or the semiconductor chip for a CPU in one of them and a GPU (Graphics Processing Unit) in the other.

By using the electronic components 17 and 18 which are not thinned in place of the electronic components 17 and 18 which are thinned plates and are hard to carry out handling, thus, it is possible to bond the electronic components 17 and 18 in predetermined positions of the flat surface 155A of the second support 155 with high precision.

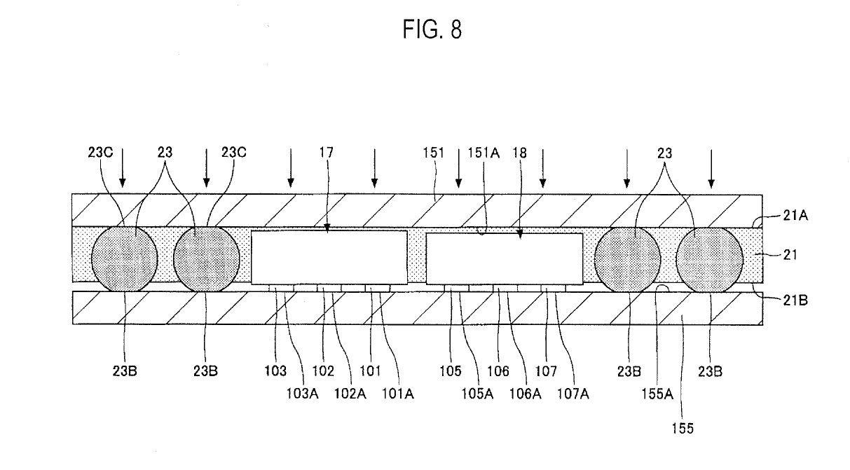

At a step shown in FIG. 8, next, the electronic components 17 and 18 bonded to the second support 155 and the first sealing resin 21 are disposed opposite to each other, and the first support 151 is then pressed in a direction turned toward the second support 155 until the connecting surface 23B of the conductive ball 23 comes in contact with the flat surface 155A of the second support 155. Thereafter, the first sealing resin 21 is completely cured to seal a part of the electronic components 17 and 18 (a first sealing step).

More specifically, in the case in which the first sealing resin 21 is constituted by a thermosetting resin, for example, the first sealing resin 21 is heated and is thus cured completely after the pressing. A thickness of the first sealing resin 21 cured completely can be set to be 200 μm, for example.

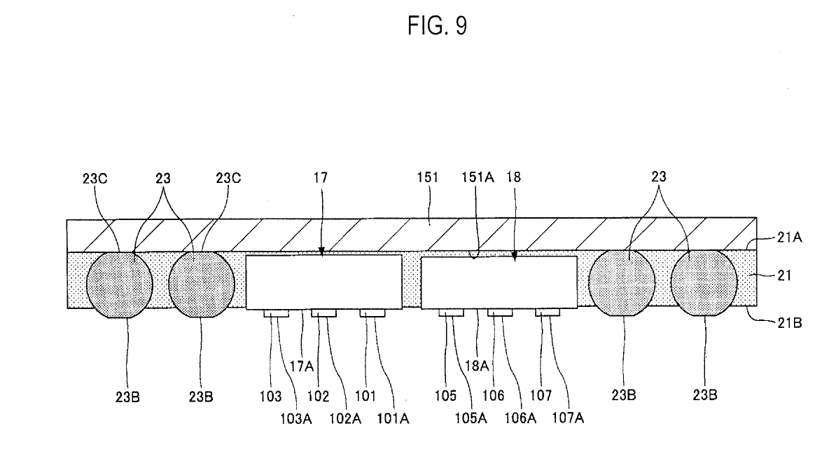

At a step shown in FIG. 9, subsequently, the second support 155 illustrated in FIG. 8 is removed (a second support removing step). Consequently, there are exposed the lower surface 21B of the first sealing resin 21, the electronic components 17 and 18 in a part exposed from the first sealing resin 21 and the conductive ball 23 in the part exposed from the first sealing resin 21.

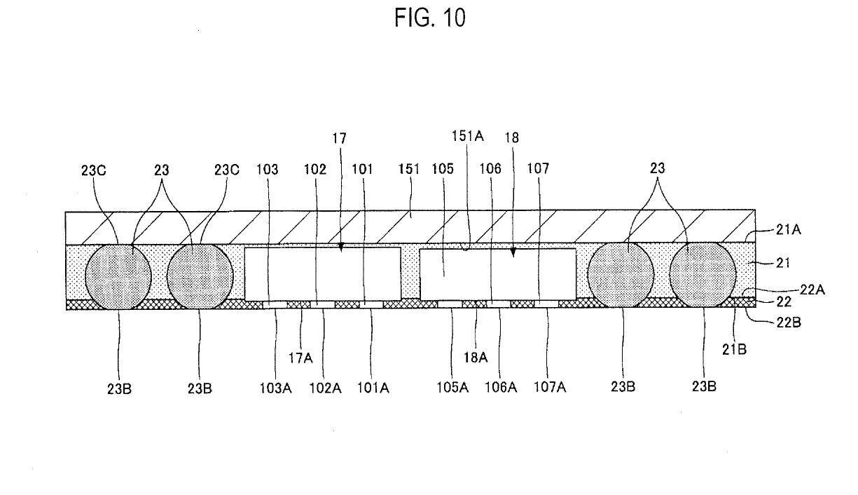

At a step shown in FIG. 10, then, there is formed a second sealing resin 22 which covers the electronic components 17 and 18 in the part exposed from the first sealing resin 21 (excluding the connecting surfaces 101A, 102A, 103A, 105A, 106A and 107A), the lower surface 21B of the first sealing resin 21 and a side surface of the conductive ball 23 in the part exposed from the first sealing resin 21 and has a multilayer wiring structure forming surface 22B disposed on a plane passing through the connecting surfaces 23B, 101A, 102A, 103A, 105A, 106A and 107A (a second sealing resin forming step).

As the second sealing resin 22, for example, it is possible to use a mold resin (for instance, a thickness of 10 μm).

It is possible to form the second sealing resin 22 by forming a mold resin to cover a lower surface of the structure shown in FIG. 9 and then polishing the mold resin until the connecting surfaces 23B, 101A, 102A, 103A, 105A, 106A and 107A are exposed from the lower surface side of the structure shown in FIG. 9, for example.

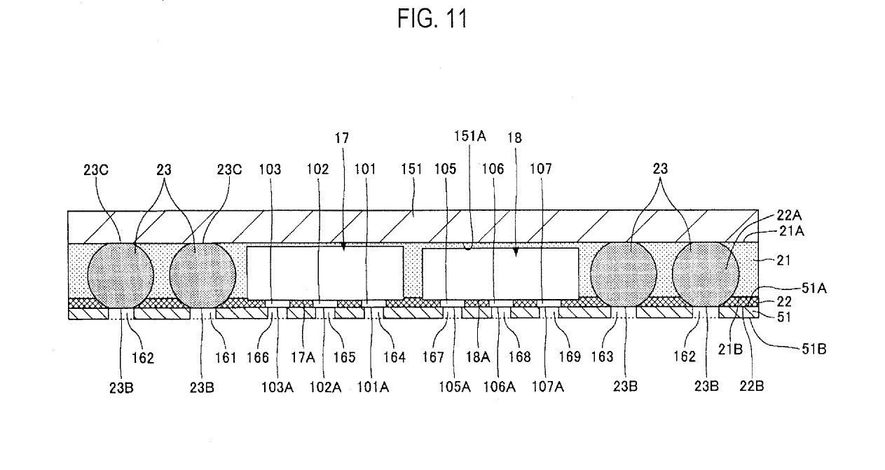

At a step shown in FIG. 11, next, an insulating layer 51 having opening portions 161 to 169 is formed on a lower surface side of the structure illustrated in FIG. 10 (the connecting surfaces 23B, 101A, 102A, 103A, 105A, 106A and 107A and the lower surface 22B of the second sealing resin 22). As the insulating layer 51, for example, it is possible to use an insulating resin film constituted by an epoxy resin. More specifically, it is possible to form the insulating layer 51 by sticking an insulating resin film (for example, a thickness of 10 μm) onto the lower surface of the structure illustrated in FIG. 10 and then carrying out a laser processing over the insulating resin film in corresponding parts to regions in which the opening portions 161 to 169 are to be formed, for instance. It is also possible to form the opening portions 161 to 169 by using photolithography or imprint in place of the laser processing.

The opening portions 161 to 163 are formed to expose the connecting surface 23B. The opening portion 164 is formed to expose the connecting surface 101A and the opening portion 165 is formed to expose the connecting surface 102A. The opening portion 166 is formed to expose the connecting surface 103A and the opening portion 167 is formed to expose the connecting surface 105A. The opening portion 168 is formed to expose the connecting surface 106A and the opening portion 169 is formed to expose the connecting surface 107A.

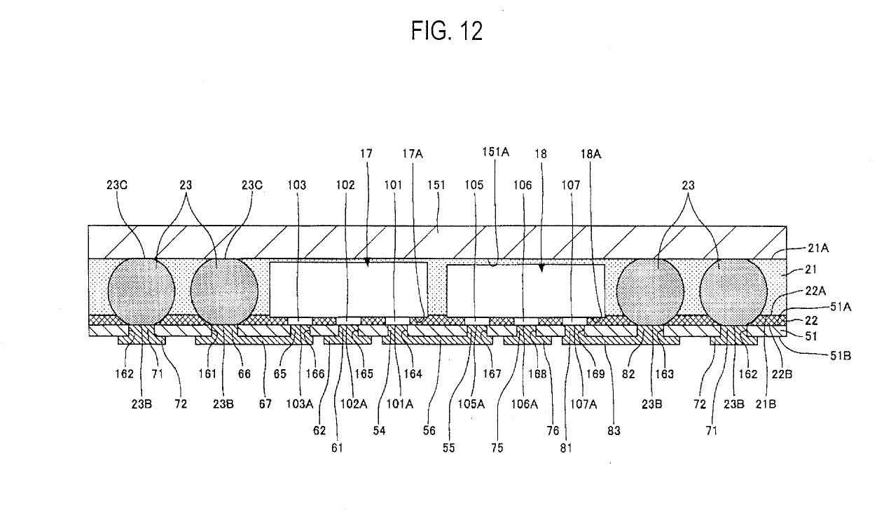

At a step shown in FIG. 12, subsequently, vias 54, 55, 61, 65, 66, 71, 75, 81 and 82 for filling the opening portions 161 to 169 are formed and wirings 56, 62, 67, 72, 76 and 83 are formed on a lower surface 51B of the insulating layer 51.

More specifically, it is possible to form the vias 54, 55, 61, 65, 66, 71, 75, 81 and 82 and the wirings 56, 62, 67, 72, 76 and 83 by a semiadditive method, for example. As materials of the vias 54, 55, 61, 65, 66, 71, 75, 81 and 82 and the wirings 56, 62, 67, 72, 76 and 83, for example, it is possible to use Cu.

The via 54 (one of components of a wiring pattern 41) is formed in the opening portion 164 so as to be directly connected to the connecting surface 101A of the electrode pad 101. The via 55 (one of the components of the wiring pattern 41) is formed in the opening portion 167 so as to be directly connected to the connecting surface 105A of the electrode pad 105. The wiring 56 is formed integrally with the vias 54 and 55.

The via 61 (one of components of a wiring pattern 42) is formed in the opening portion 165 so as to be directly connected to the connecting surface 102A of the electrode pad 102. The wiring 62 is formed integrally with the via 61.

The via 65 (one of components of a wiring pattern 43) is formed in the opening portion 166 so as to be directly connected to the connecting surface 103A of the electrode pad 103. The via 66 (one of the components of the wiring pattern 43) is formed in the opening portion 161 so as to be directly connected to the connecting surface 23B of the conductive ball 23. The wiring 67 is formed integrally with the vias 65 and 66.

The via 71 (one of components of a wiring pattern 44) is formed in the opening portion 162 so as to be directly connected to the connecting surface 23B of the conductive ball 23. The wiring 72 is formed integrally with the via 71. The via 75 (one of components of a wiring pattern 45) is formed in the opening portion 168 so as to be directly connected to the connecting surface 106A of the electrode pad 106. The wiring 76 is formed integrally with the via 75.

The via 81 (one of components of a wiring pattern 46) is formed in the opening portion 169 so as to be directly connected to the connecting surface 107A of the electrode pad 107. The via 82 is formed in the opening portion 163 so as to be directly connected to the connecting surface 23B. The wiring 83 is formed integrally with the vias 81 and 82.

By directly connecting the electrode pads 101 to 103 and 105 to 107 of the electronic components 17 and 18 to the wiring patterns 41 to 43, 45 and 46, thus, it is possible to reduce the size in the thickness direction of the semiconductor device 11 more greatly as compared with the related-art semiconductor device 200 in which the electronic component 212 and the wiring pattern 219 are electrically connected to each other through the bump or the metal wire (see FIG. 1).

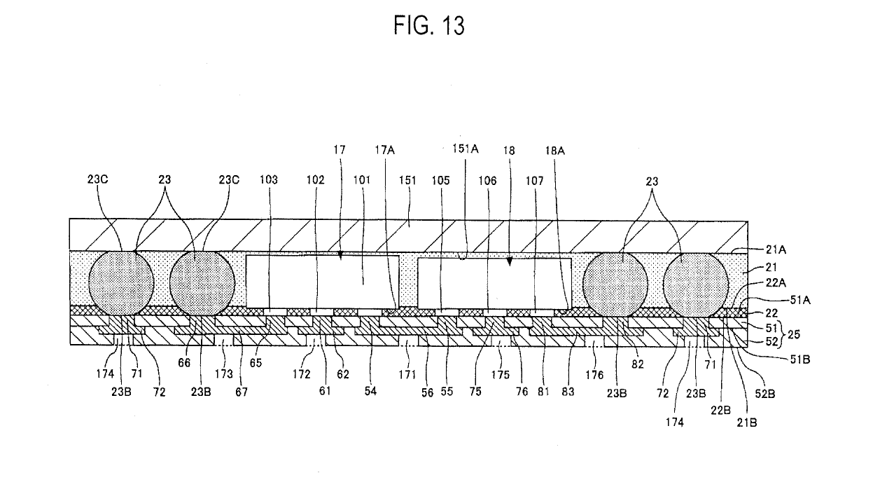

At a step shown in FIG. 13, then, an insulating layer 52 is formed on the lower surface 51B of the insulating layer 51. The insulating layer 52 has opening portions 171 to 176 and covers a part of the wirings 56, 62, 67, 72, 76 and 83.

As the insulating layer 52, for example, it is possible to use an insulating resin film constituted by an epoxy resin. More specifically, it is possible to form the insulating layer 52 by sticking an insulating resin film (for example, a thickness of 20 μm) onto the lower surface of the structure illustrated in FIG. 12 and then carrying out a laser processing over the insulating resin film in corresponding parts to regions in which the opening portions 171 to 176 are to be formed, for instance. It is also possible to form the opening portions 171 to 176 by using photolithography or imprint in place of the laser processing.

The opening portion 171 is formed to expose a part of a lower surface of the wiring 56. The opening portion 172 is formed to expose a part of a lower surface of the wiring 62. The opening portion 173 is formed to expose a part of a lower surface of the wiring 67. The opening portion 174 is formed to expose a part of a lower surface of the wiring 72. The opening portion 175 is formed to expose a part of a lower surface of the wiring 76. The opening portion 176 is formed to expose a part of a lower surface of the wiring 83.

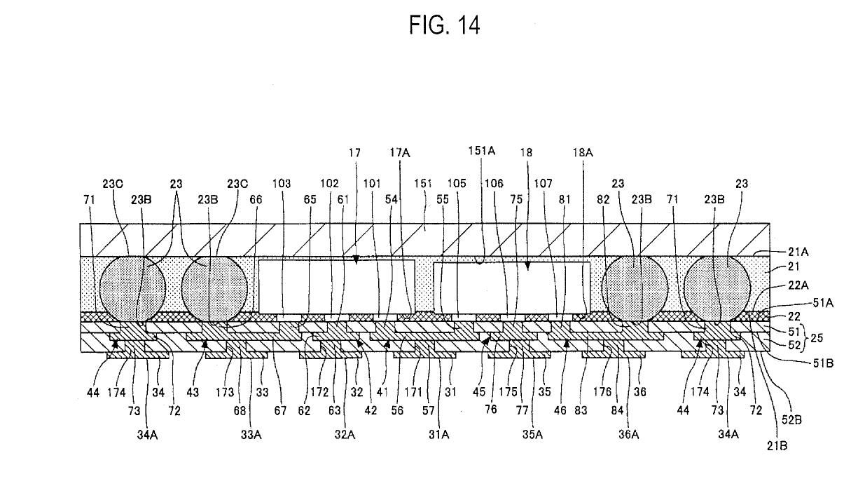

At a step shown in FIG. 14, subsequently, vias 57, 63, 68, 73, 77 and 84 for filling the opening portions 171 to 176 are formed and external connecting pads 31 to 36 having connecting surfaces 31A, 32A, 33A, 34A, 35A and 36A are formed on a lower surface 52B of the insulating layer 52.

More specifically, the vias 57, 63, 68, 73, 77 and 84 and the external connecting pads 31 to 36 can be formed by a semiadditive method, for example. As materials of the vias 57, 63, 68, 73, 77 and 84 and the external connecting pads 31 to 36, for example, it is possible to use Cu.

The via 57 is formed in the opening portion 171 so as to be connected to the wiring 56. The external connecting pad 31 is formed integrally with the via 57. The via 63 is formed in the opening portion 172 so as to be connected to the wiring 62. The external connecting pad 32 is formed integrally with the via 63.

The via 68 is formed in the opening portion 173 so as to be connected to the wiring 67. The external connecting pad 33 is formed integrally with the via 68. The via 73 is formed in the opening portion 174 so as to be connected to the wiring 72. The external connecting pad 34 is formed integrally with the via 73.

The via 77 is formed in the opening portion 175 so as to be connected to the wiring 76. The external connecting pad 35 is formed integrally with the via 77. The via 84 is formed in the opening portion 176 so as to be connected to the wiring 83. The external connecting pad 36 is formed integrally with the via 84.

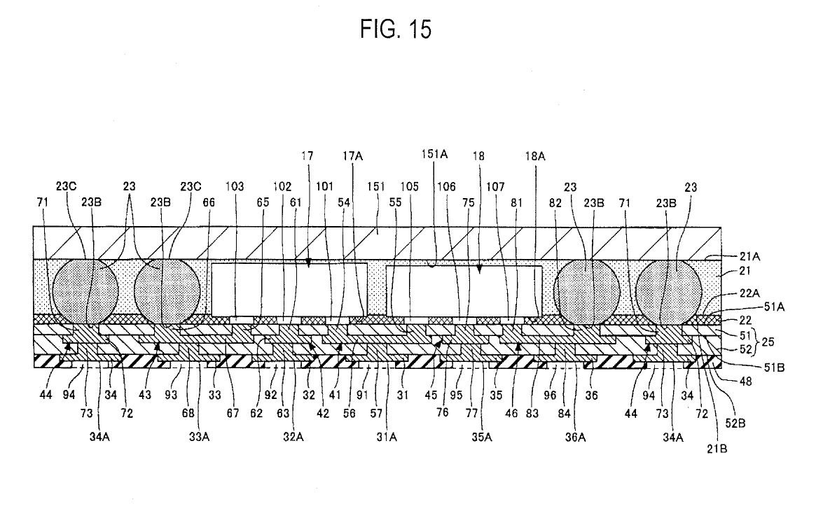

At a step shown in FIG. 15, then, a solder resist layer 48 having opening portions 91 to 96 is formed on the lower surface 52B of the insulating layer 52. The opening portion 91 is formed to expose the connecting surface 31A and the opening portion 92 is formed to expose the connecting surface 32A. The opening portion 93 is formed to expose the connecting surface 33A and the opening portion 94 is formed to expose the connecting surface 34A. The opening portion 95 is formed to expose the connecting surface 35A. The opening portion 96 is formed to expose the connecting surface 36A.

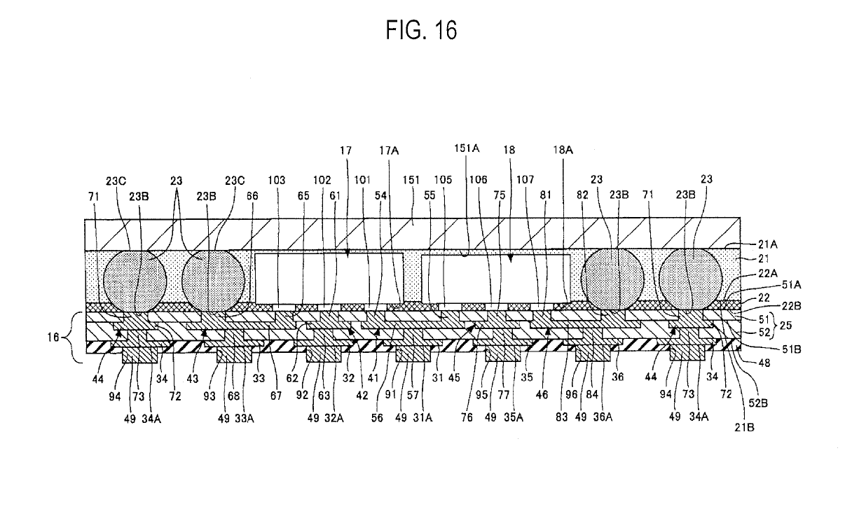

At a step shown in FIG. 16, thereafter, an external connecting terminal 49 is formed on the connecting surfaces 31A, 32A, 33A, 34A, 35A and 36A. Consequently, a multilayer wiring structure 16 is formed on the lower surface 22B of the second sealing resin 22. The steps shown in FIGS. 11 to 16 correspond to “a multilayer wiring structure forming step”.

As the external connecting terminal 49, for example, it is possible to use a metal post. Although the case in which the metal post is used as the external connecting terminal 49 is illustrated as an example in FIG. 16, it is also possible to use a conductive ball (for example, a solder ball) as the external connecting terminal 49 in place of the metal post, for instance.

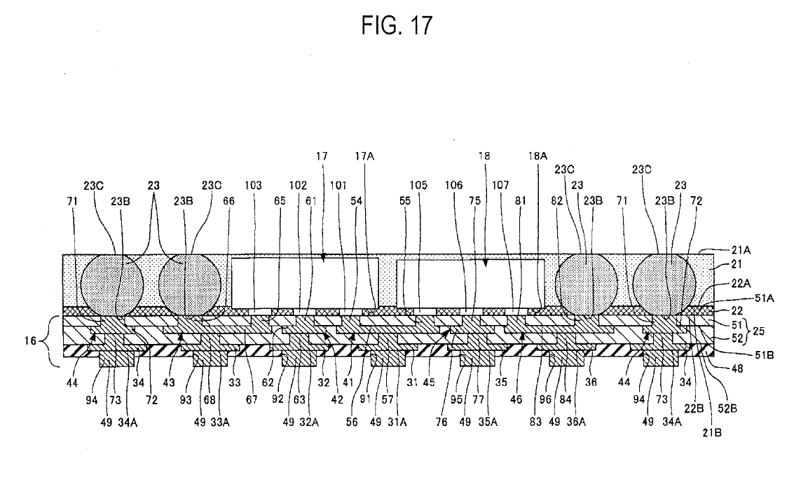

At a step shown in FIG. 17, next, the first support 151 provided in the structure shown in FIG. 16 is removed (a first support removing step). In the case in which the first support 151 is a silicon substrate, it is removed by carrying out etching over the silicon substrate through a dry etching process, for example. In the case in which the first support 151 is a Cu plate, moreover, it is removed by carrying out wet etching over the Cu plate, for example.

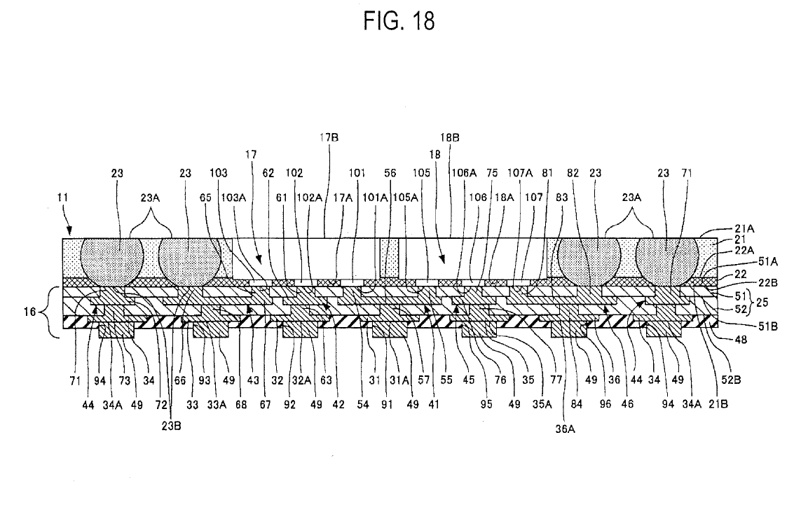

At a step shown in FIG. 18, subsequently, the conductive ball 23, the first sealing resin 21 and the electronic components 17 and 18 are polished (for example, CMP (Chemical Mechanical Polishing)) from an upper surface side of the structure shown in FIG. 17 (a side on which the first support 151 is disposed). Thus, the electronic components 17 and 18 are changed into thinned plates and a connecting surface 23A to be a second connecting surface is formed on the conductive ball 23, and furthermore, the connecting surface 23A, back faces 17B and 18B of the electronic components 17 and 18 on the polishing side and an upper surface 21A of the first sealing resin 21 on the polishing side are disposed on the same plane (a polishing step). Consequently, the semiconductor device 11 is manufactured.

Thus, the connecting surface 23A formed on the conductive ball 23, the back faces 17B and 18B of the electronic components 17 and 18 on the polishing side and the upper surface 21A of the first sealing resin 21 subjected to the polishing are disposed on the same plane by the execution of the polishing. Consequently, an upper surface of the semiconductor device 11 (a surface of the semiconductor device 11 on a side to which a semiconductor device 12 is to be connected) can be set to be flat.

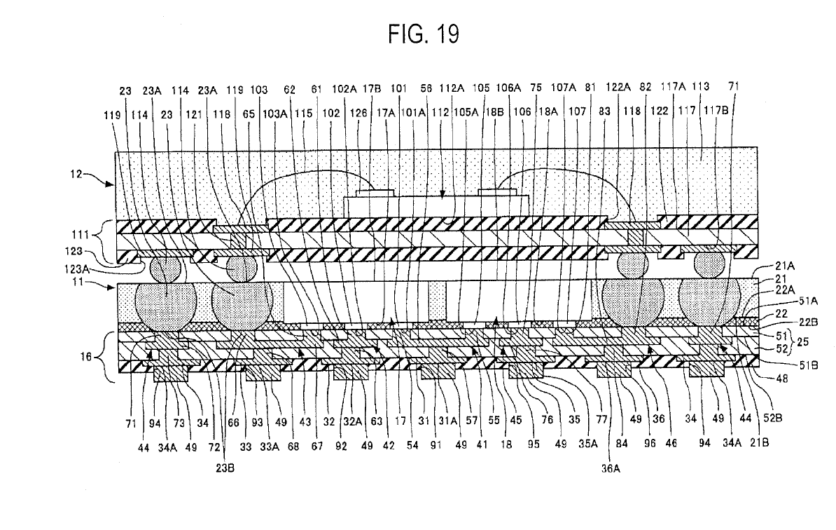

Consequently, it is possible to reduce a diameter (a height) of an internal connecting terminal 114 which is provided in the semiconductor device 12 shown in FIG. 19 to be described below and is bonded to the conductive ball 23 provided in the semiconductor device 11. Therefore, it is possible to reduce the size in the thickness direction of the electronic apparatus 10.

At a step shown in FIG. 19, then, the semiconductor device 12 formed by a well-known technique is prepared, and furthermore, the semiconductor device 12 is mounted on the semiconductor device 11 in such a manner that the connecting surface 23A of the conductive ball 23 provided in the semiconductor device 11 comes in contact with the internal connecting terminal 114 provided in the semiconductor device 12.

As the internal connecting terminal 114, for example, it is possible to use a solder ball. As described above, moreover, the upper surface of the semiconductor device 11 which is opposed to the semiconductor device 12 is set to be flat. Therefore, it is possible to reduce the diameter (height) of the internal connecting terminal 114. More specifically, the diameter (height) of the internal connecting terminal 114 can be set to be 30 μm, for example.

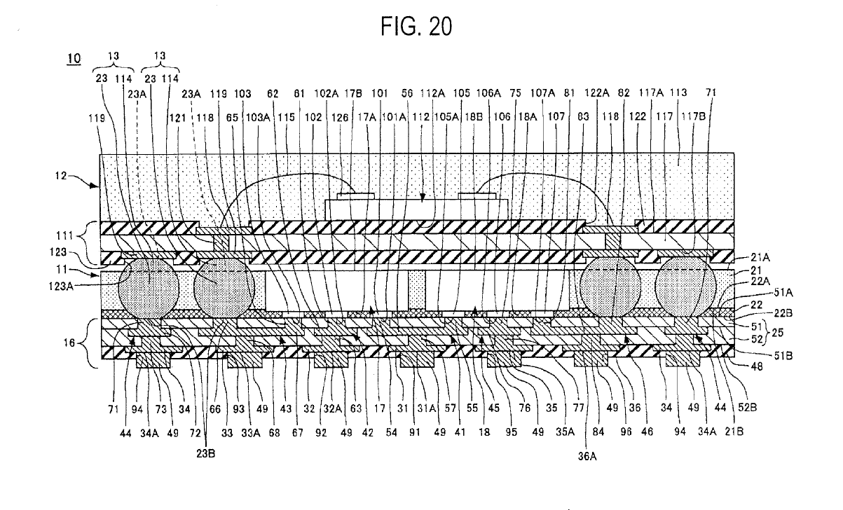

At a step shown in FIG. 20, thereafter, the conductive ball 23 and the internal connecting terminal 114 are molten by heating and are thus bonded to each other. Consequently, there is manufactured the electronic apparatus 10 according to the first embodiment which includes the semiconductor device 11 and the semiconductor device 12 connected electrically to the semiconductor device 11.

According to the method of manufacturing a semiconductor device in accordance with the embodiment, the multilayer wiring structure 16 is formed on the multilayer wiring structure forming surface 22B, the connecting surfaces 101A, 102A, 103A, 105A, 106A and 107A of the electronic components 17 and 18 and the connecting surface 23B of the conductive ball 23 in such a manner that the wiring patterns 41 to 43, 45 and 46 are directly connected to the connecting surfaces 101A, 102A, 103A, 105A, 106A and 107A of the electronic components 17 and 18. Consequently, it is possible to reduce the size in the thickness direction of the semiconductor device 11 more greatly as compared with the related-art semiconductor device 200 in which the electronic component 212 and the wiring pattern 219 are electrically connected to each other through the bump or the metal wire (see FIG. 1).

Moreover, the electronic components 17 and 18 bonded to the second support 155 and the first sealing resin 21 are disposed opposite to each other, and the first support 151 is pressed in the direction turned toward the second support 155 until the contact surface 23B of the conductive ball 23 and the flat surface 155A of the second support 155 come in contact with each other. Thereafter, the first sealing resin 21 is cured completely to seal the side surfaces of the electronic components 17 and 18. Consequently, the first sealing resin 21 functions as a reinforcing member for reinforcing a strength of the multilayer wiring structure 16. Thus, it is possible to enhance a strength of the semiconductor device 11.

The electronic apparatus 130 (see FIG. 3) according to the variant of the first embodiment can be formed as follows. The same processings as those in the steps shown in FIGS. 4 to 18 are carried out to form the semiconductor device 11, the wiring board 132 formed by a well-known technique is then stacked on the upper surface of the semiconductor device 11, the conductive ball 23 and the solder 145 are thereafter molten, and subsequently, the conductive ball 23 and the solder 145 are bonded to each other. Next, the internal connecting terminal 114 provided in the semiconductor device 12 formed by a well-known technique is connected to the pad 137 disposed in the wiring board 132. Thus, the electronic apparatus 130 can be formed.

### Second Embodiment

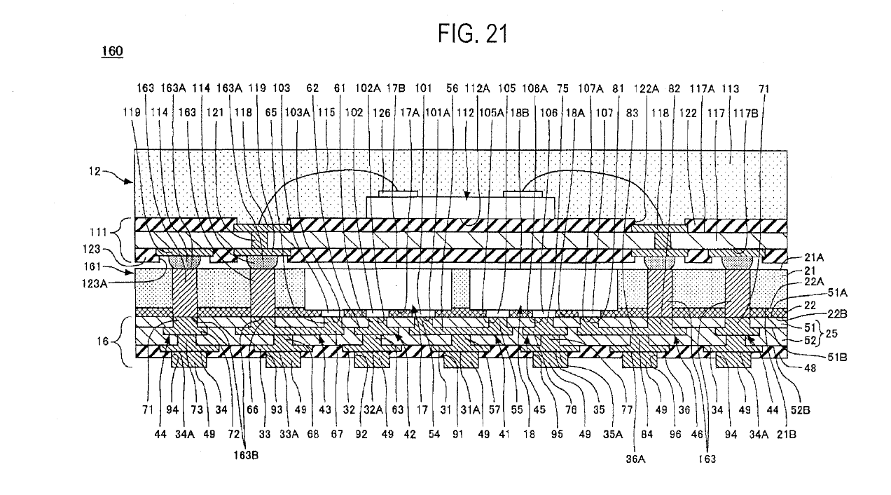

FIG. 21 is a sectional view showing an electronic apparatus according to a second embodiment of the invention. In FIG. 21, the same components as those of the electronic apparatus 10 according to the first embodiment have the same designations.

With reference to FIG. 21, an electronic apparatus 160 according to the second embodiment has the same structure as that of the electronic apparatus 10 except that a semiconductor device 161 is disposed in place of the semiconductor device 11 provided in the electronic apparatus 10 according to the first embodiment.

The semiconductor device 161 has the same structure as that of the semiconductor device 11 except that a metal post 163 is provided as a conductive member in place of the conductive ball 23 disposed in the semiconductor device 11 described in the first embodiment.

The metal post 163 is provided to penetrate through first and second sealing resins 21 and 22 in opposed parts to vias 66, 71 and 82. The metal post 163 has a connecting surface 163B to be a first connecting surface and a connecting surface 163A to be a second connecting surface.

The connecting surface 163B is flat. The connecting surface 163B is connected to an upper end of one of the vias 66, 71 and 82. Consequently, the metal post 163 is electrically connected to a multilayer wiring structure 16 and electronic components 17 and 18.

The connecting surface 163A is flat. The connecting surface 163A is constituted on almost the level with back faces 17B and 18B of the electronic components 17 and 18 and an upper surface 21A of the first sealing resin 21. In other words, the connecting surface 163A, the back faces 17B and 18B of the electronic components 17 and 18 and the upper surface 21A of the first sealing resin 21 are disposed on the same plane. The connecting surface 163A is connected to an internal connecting terminal 114 provided in a semiconductor device 12. Consequently, the metal post 163 is electrically connected to the semiconductor device 12.

The metal post 163 having the structure electrically connects the semiconductor device 12 to the multilayer wiring structure 16 and the electronic components 17 and 18. As the metal post 163, for example, it is possible to use a Cu post. A thickness of the metal post 163 can be set to be 200 μm, for example.

The semiconductor device 161 according to the second embodiment which has the structure can obtain the same advantages as those of the semiconductor device 11 according to the first embodiment.

Moreover, the electronic apparatus 160 according to the second embodiment which includes the semiconductor device 161 having the structure and the semiconductor device 12 to be electrically connected to the semiconductor device 161 can obtain the same advantages as those of the electronic apparatus 10 according to the first embodiment.

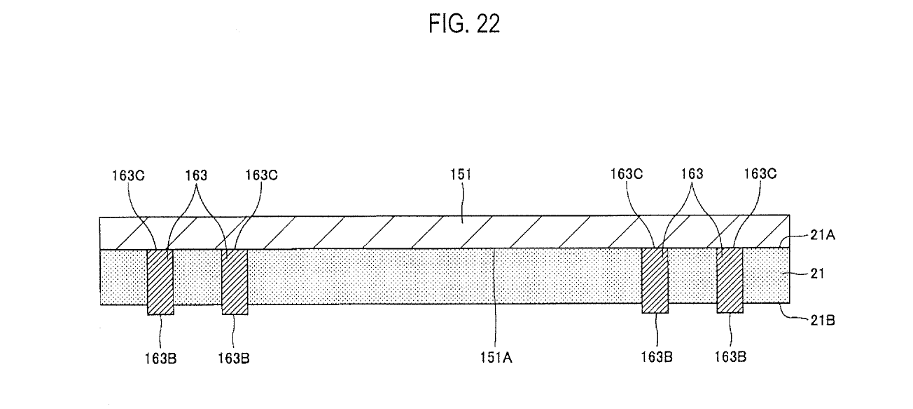

FIGS. 22 to 28 are views showing a process for manufacturing the electronic apparatus according to the second embodiment of the invention. In FIGS. 22 to 28, the same components as those of the electronic apparatus 160 according to the second embodiment have the same designations.

With reference to FIGS. 22 to 28, description will be given to a method of manufacturing the electronic apparatus 160 according to the second embodiment. In the description of the method of manufacturing the electronic apparatus 160 according to the second embodiment, explanation will also be given to a method of manufacturing the semiconductor device 161 according to the second embodiment.

First of all, the same processing as the step shown in FIG. 4 described in the first embodiment is carried out to form the structure illustrated in FIG. 4 (a first sealing resin forming step).

A thickness of a first sealing resin 21 in this stage is greater than that of the first sealing resin 21 shown in FIG. 21 described above (for example, 200 μm). The thickness of the first sealing resin 21 shown in FIG. 4 can be set to be 800 μm, for example.

At a step shown in FIG. 22, subsequently, there is prepared a plurality of metal posts 163 having a height to be a greater value than a value of the thickness of the first sealing resin 21 set in a semicuring state and including a flat surface 163C and a connecting surface 163B (a first connecting surface) disposed on an opposite side to the flat surface 163C. Subsequently, the flat surfaces 163C of the metal posts 163 and a surface 151A of a first support 151 are caused to come in contact with each other in order to penetrate through the first sealing resin 21 from a lower surface 21B side of the first sealing resin 21, and furthermore, the metal posts 163 are provided in the first sealing resin 21 in a state in which the contact surfaces 163B are protruded from the first sealing resin 21 (a metal post providing step).

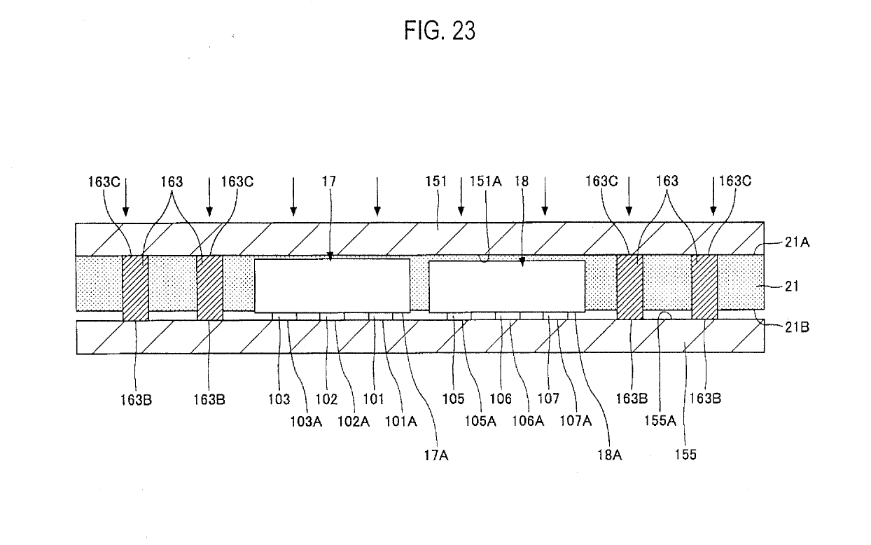

At a step shown in FIG. 23, then, there is prepared the second support 155 to which the electronic components 17 and 18 are bonded as illustrated in FIG. 7 described in the first embodiment (an electronic component bonding step). Next, the structure shown in FIG. 22 is disposed above the second support 155 in such a manner that the electronic components 17 and 18 are opposed to the first sealing resin 21.

Then, the first support 151 is pressed in a direction turned toward the second support 155 until connecting surfaces 101A, 102A, 103A, 105A, 106A, 107A and 163B come in contact with a surface 155A of the second support 155. Thereafter, the first sealing resin 21 is cured completely to seal side surfaces of the electronic components 17 and 18 (a first sealing step).

Thus, the metal posts 163 having a smaller variation in the height than that of conductive balls 23 are used as a conductive member for electrically connecting a multilayer wiring structure 16 to a semiconductor device 12 in, place of the conductive balls 23. Consequently, there is not required the conductive ball crushing step of causing the heights of the conductive balls 23 to be equal to each other as described in the first embodiment. Therefore, it is possible to reduce a manufacturing cost of the semiconductor device 161.

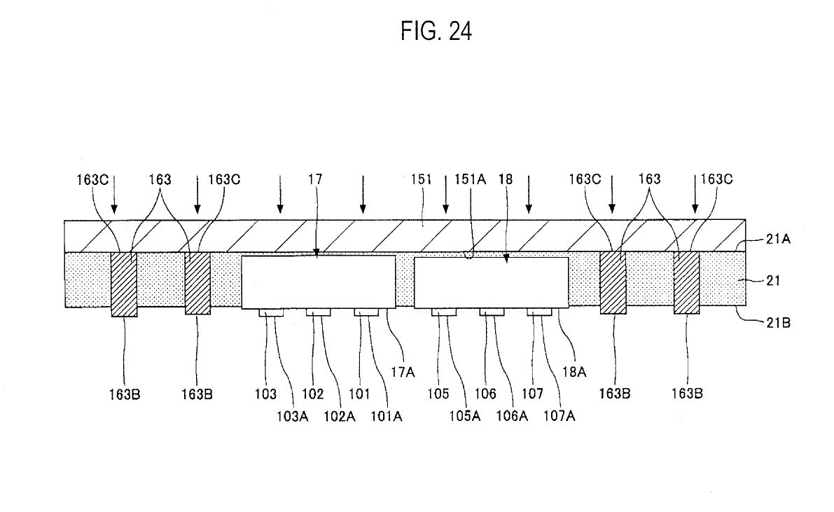

At a step shown in FIG. 24, next, the second support 155 illustrated in FIG. 23 is removed (a second support removing step). Consequently, there are exposed the lower surface 21B of the first sealing resin 21, electrode pad forming surfaces 17A and 18A of the electronic components 17 and 18, and the contact surface 163B of the metal post 163.

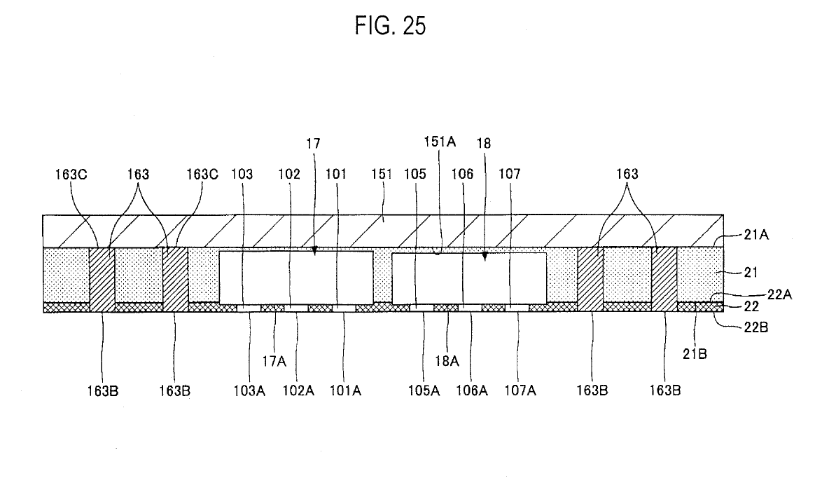

At a step shown in FIG. 25, subsequently, there is formed a second sealing resin 22 in which the connecting surfaces 101A, 102A, 103A, 105A, 106A, 107A and 163B are exposed to the lower surface 21B of the first sealing resin 21, the electronic components 17 and 18 in parts exposed from the first sealing resin 21 and a side surface of the metal post 163 in a part exposed from the first sealing resin 21 and which has a multilayer wiring structure forming surface 22B disposed on the same plane with the connecting surfaces 101A, 102A, 103A, 105A, 106A, 107A and 163B (a second sealing resin forming step).

The second sealing resin can be formed by the same technique as that in the step shown in FIG. 10 described in the first embodiment. As the second sealing resin 22, for example, it is possible to use a mold resin (for example, a thickness of 10 μm).

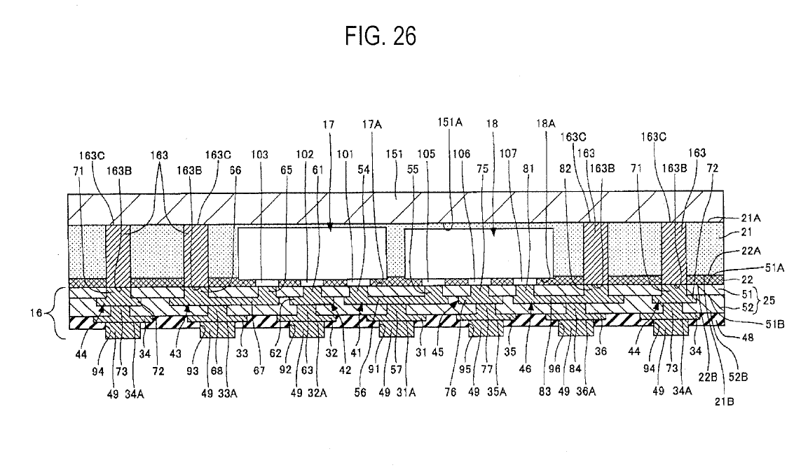

At a step shown in FIG. 26, then, the same processings as those in the steps illustrated in FIGS. 11 to 16 described in the first embodiment are carried out to form the multilayer wiring structure 16 on the lower surface 22B of the second sealing resin 22 and the connecting surfaces 101A, 102A, 103A, 105A, 106A, 107A and 163B in such a manner that wiring patterns 41 to 43 are directly connected to the connecting surfaces 101A, 102A and 103A and wiring patterns 41, 45 and 46 are directly connected to the connecting surfaces 105A, 106A and 107A (a multilayer wiring structure forming step).

By directly connecting electrode pads 101 to 103 and 105 to 107 of the electronic components 17 and 18 to the wiring patterns 41 to 43, 45 and 46, thus, it is possible to reduce a size in a thickness direction of the semiconductor device 161 more greatly as compared with the related-art semiconductor device 200 in which the electronic component 212 and the wiring pattern 219 are electrically connected to each other through the bump or the metal wire (see FIG. 1).

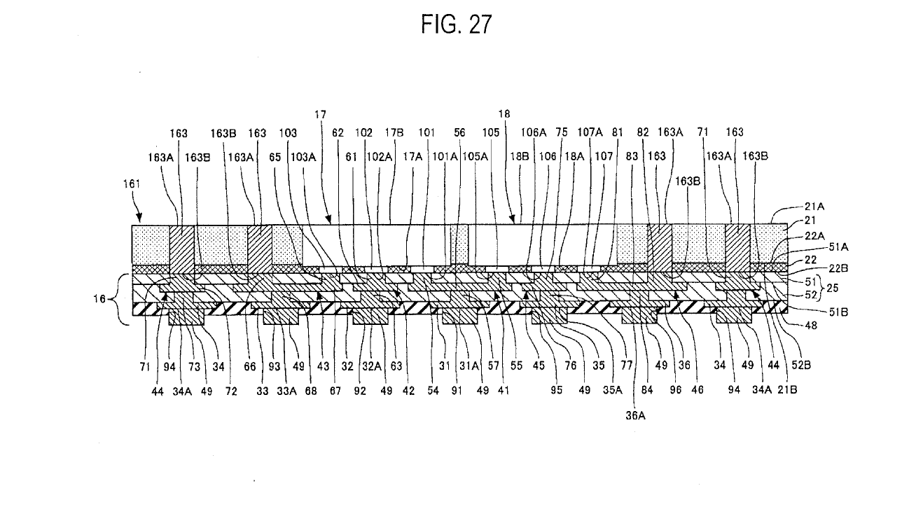

At a step shown in FIG. 27, thereafter, the same processing as that in the step illustrated in FIG. 17 described in the first embodiment is carried out to remove the first support 151 shown in FIG. 26 (a first support removing step).

Subsequently, the metal post 163, the first sealing resin 21 and the electronic components 17 and 18 are polished (polishing using CMP (Chemical Mechanical Polishing), for example) from a side on which the first support 151 is provided to change the electronic components 17 and 18 into thinned plates, thereby forming a connecting surface 163A (a second connecting surface) on the metal post 163 (a polishing step).

At this time, back faces 17B and 18B of the electronic components 17 and 18 on the polishing side, an upper surface 21A of the first sealing resin 21 on the polishing side and the connecting surface 163A of the metal post 163 are disposed on the same plane. Consequently, the semiconductor device 161 according to the second embodiment is manufactured.

By disposing, on the same plane, the connecting surface 163A formed on the metal post 163 through the polishing, the back faces 17B and 18B of the electronic components 17 and 18 on the polishing side and the surface 21A of the first sealing resin 21 on the polishing side, moreover, it is possible to cause an upper surface of the semiconductor device 161 (a surface of the semiconductor device 161 on a side to which the semiconductor device 12 is connected) to be flat.

Consequently, it is possible to reduce a diameter (a height) of an internal connecting terminal 114 which is provided in the semiconductor device 12 and is bonded to the metal post 163. Therefore, it is possible to reduce a size in a thickness direction of the electronic apparatus 160.

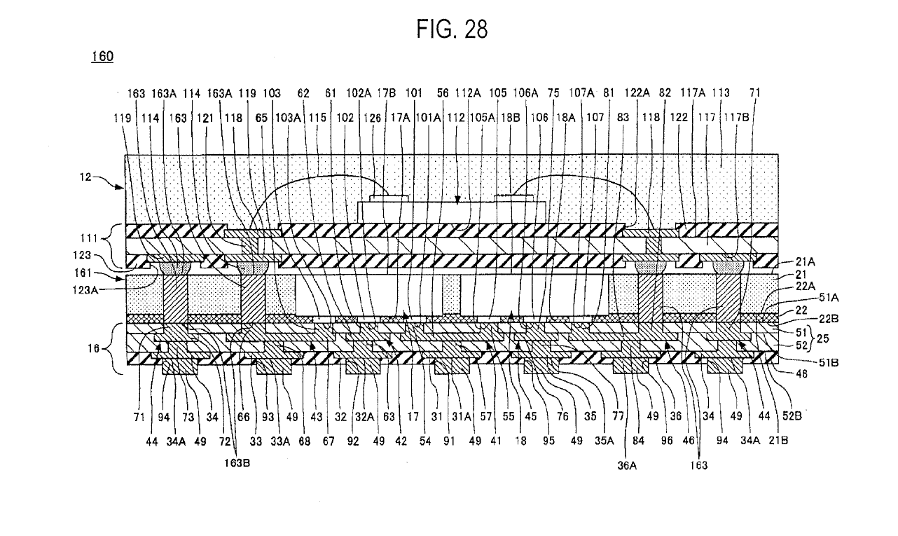

At a step shown in FIG. 28, next, the semiconductor device 12 is disposed on the semiconductor device 161 in such a manner that the connecting surface 163A provided in the semiconductor device 161 comes in contact with the internal connecting terminal 114 provided in the semiconductor device 12, and the internal connecting terminal 114 is then molten and is thus connected to the metal post 163. Consequently, there is manufactured the electronic apparatus 160 according to the second embodiment which includes the semiconductor device 161 and the semiconductor device 12 connected electrically to the semiconductor device 161.

According to the method of manufacturing a semiconductor device in accordance with the embodiment, the metal posts 163 having a smaller variation in the height than that of conductive balls 23 are used as the conductive member for electrically connecting the multilayer wiring structure 16 to the semiconductor device 12 in place of the conductive balls 23. Consequently, there is not required the conductive ball crushing step of causing the heights of the conductive balls 23 to be equal to each other as described in the first embodiment. Therefore, it is possible to reduce the manufacturing cost of the semiconductor device 161.

Moreover, the method of manufacturing the semiconductor device 161 according to the second embodiment can obtain the same advantages as those of the method of manufacturing the semiconductor device 11 according to the first embodiment.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

Although the description has been given by taking, as an example, the case in which two electronic components (the electronic components 17 and 18) are provided in the semiconductor devices 11 and 161 according to the first and second embodiments, for instance, the number of the electronic components to be disposed on the multilayer wiring structure 16 is not restricted thereto. In other words, the number of the electronic components to be disposed on the multilayer wiring structure 16 may be one, or three or more.

What is claimed is:

1. A semiconductor device comprising:
an electronic component including an electrode pad, an electrode pad forming surface on which the electrode pad is formed, and a back face positioned on an opposite side to the electrode pad forming surface;
a conductive member which includes a first connecting surface disposed on an electrode pad forming surface side and a second connecting surface disposed on a back face side;
a first sealing resin which includes a first surface disposed on the electrode pad forming surface side and a second surface disposed on the back face side, and seals a side surface of the electronic component and a side surface of the conductive member;
a second sealing resin which is provided on the first surface of the first sealing resin, and seals the electrode pad, the electrode pad forming surface and a part of the conductive member in a state that a connecting surface of the electrode pad and the first connecting surface of the conductive member are exposed from the second sealing resin; and
a multilayer wiring structure which is provided on a surface of the second sealing resin from which the connecting surface of the electrode pad and the first connecting surface of the conductive member are exposed, and includes a plurality of stacked insulating layers and a wiring pattern,
wherein the wiring pattern is connected to the connecting surface of the electrode pad and the first connecting surface of the conductive member.

2. The semiconductor device according to claim 1, wherein the conductive member is a conductive ball or a metal post.

3. The semiconductor device according to claim 1, wherein a thickness of the first sealing resin is greater than a thickness of the second sealing resin and a thickness of the multilayer wiring structure.

4. The semiconductor device according to claim 1, wherein the wiring pattern includes a via directly connected to the connecting surface of the electrode pad.

5. The semiconductor device according to claim 1, wherein the connecting surface of the electrode pad and the first connecting surface of the conductive member are disposed on the same plane.

6. A method of manufacturing a semiconductor device including a multilayer wiring structure having a plurality of stacked insulating layers and a wiring pattern, and an electronic component having an electrode pad to be electrically connected to the wiring pattern, the method comprising:
a first step of forming a first sealing resin set in a semicuring state on a surface of a first support;
a second step of pushing a plurality of conductive members against the surface of the first support to penetrate through the first sealing resin, thereby providing the conductive members in the first sealing resin in a state in which a first connecting surface of each of the conductive members is protruded from the first sealing resin;
a third step of bonding the electronic component to a second support in such a manner that a flat surface of the second support comes in contact with a connecting surface of the electrode pad of the electronic component;
a fourth step of disposing the electronic component bonded to the second support and the first sealing resin opposite to each other and then pressing the first support and the second support to each other until the first connecting surface and the flat surface of the second support come in contact with each other, and thereafter curing the first sealing resin completely, thereby sealing a side surface of the electronic component;
a fifth step of removing the second support after the fourth step;
a sixth step of forming a second sealing resin on a surface of the first sealing resin positioned on an opposite side to a surface coming in contact with the first support in a state that the connecting surface of the electrode pad of the electronic component and the first connecting surface of the conductive member are exposed from the second sealing resin;
a seventh step of forming the multilayer wiring structure on the surface of the second sealing resin from which the connecting surface of the electrode pad of the electronic component and the first connecting surface of the conductive member are exposed in a state that the wiring pattern is connected to the connecting surface of the electrode pad of the electronic component and the first connecting surface of the conductive member; and
an eighth step of removing the first support after the seventh step.

7. The method of manufacturing a semiconductor device according to claim 6, further comprising:
a ninth step of polishing the conductive member, the first sealing resin and the electronic component from a side on which the first support is provided after the eighth step so that the electronic component is changed into a thinned plate and, a second connecting surface formed on the conductive member through the polishing, a back face of the electronic component which is subjected to the polishing and a surface of the first sealing resin on a polishing side are disposed on the same plane.

8. The method of manufacturing a semiconductor device according to claim 6, wherein the conductive member is a conductive ball or a metal post.

9. An electronic apparatus comprising:
the semiconductor device according to claim 1; and
another semiconductor device which is disposed on a second surface side of the first sealing resin of the semiconductor device, and includes a connecting terminal being electrically connected to the second connecting surface of the conductive member of the semiconductor device.
